(19) United States
(12) Patent Application Publication
(10) Pub. No.: US 2025/0246398 A1
(43) Pub. Date: Jul. 31, 2025

(54) CHARGED PARTICLE BEAM DEVICE AND METHOD FOR OUTPUTTING IMAGE DATA OF INTEREST

(71) Applicant: HITACHI HIGH-TECH CORPORATION, Minato-ku, Tokyo (JP)

(72) Inventors: Hiroyuki YAMAMOTO, Tokyo (JP); Takeshi Ohmori, Tokyo (JP); Shunya Tanaka, Tokyo (JP); Hirofumi Sato, Tokyo (JP)

(21) Appl. No.: 18/856,757

(22) PCT Filed: Jun. 14, 2022
(86) PCT No.: PCT/JP2022/023817

§ 371 Date: Oct. 14, 2024

(51) Int. Cl. H01J 37/22; H01J 37/244; H01J 37/28

(52) U.S. Cl. CPC H01J 37/22; H01J 37/244; H01J 37/28; H01J 2237/1532; H01J 2237/221

(57) ABSTRACT

A charged particle beam device includes: a sample stage configured to move a sample; an imaging unit configured to acquire observation image data of the sample; an output unit configured to digitalize an operating status of the charged particle beam device and output operating status time series data; a display unit configured to display a graphical user interface for displaying the observation image data and inputting an observation setting parameter; and a computer system configured to store time series image data in which the observation image data is arranged in time series and execute arithmetic processing relating to the operating status time series data and the observation image data. The charged particle beam device automatically determines a time-point that matches a predetermined specific variation pattern based on the operating status time series data, and acquires observation image data corresponding to the time-point from the time series image data and outputs the observation image data as image data of interest.

### TECHNICAL FIELD

The present invention relates to a charged particle beam device and a method for outputting image data of interest.

### BACKGROUND ART

With the evolution of the semiconductor devices in recent years, a device structure thereof has become complicated. For a semiconductor maker that manufactures an advanced device, how to develop a process for such a device quickly and efficiently is an important issue. In semiconductor process development, it is essential to optimize a condition for processing a deposited material on a silicon (Si) wafer into a designed shape. Therefore, it is necessary to observe a pattern processing shape in a cross section.

Since a processing pattern of an advanced semiconductor device is a nanometer-level fine structure, a charged particle beam device such as a transmission electron microscope (TEM) or a scanning electron microscope (SEM) having high resolution is used for observing a pattern processing shape in a cross section.

Currently, processing shape observation of a wafer cross section using a charged particle beam device has been entrusted to work to be executed by a person, and it takes much time and effort in searching for an observation visual field and imaging work. Therefore, in order to speed up and improve the efficiency of semiconductor process development, there is a demand for a device that can automate the observation work as much as possible and obtain large amounts of observation data at high speed and with minimal manpower.

With respect to an object to be observed such as a metal material or a biological sample other than a semiconductor, there is an increasing demand for a device capable of acquiring a large amount of observation data at high speed and with minimal manpower, for reasons such as the progress of the material informatics technology.

By utilizing machine learning and AI technology of image processing, it is possible to automatically detect a characteristic object during observation, and a work load for an operator in adjusting a visual field to a target observation position is reduced. For example, in the semiconductor process development, a plurality of wafer samples processed in a series of experimental series may be observed. Once a feature identifier for the object is configured using machine learning, it is possible to automate the process from visual field search to pattern observation for similar wafer samples. However, since a layout of a pattern also changes in another experimental series, it is necessary to newly configure an identification model for the object in a certain cycle. Since a large amount of training image data is indispensable for configuring an identification model (feature identifier) by machine learning, there is a problem that a large work load is still generated for the operator to collect the training image data.

The training image data is an image including an object focused by the operator, and it is also possible to newly acquire an image by the observation work or to retrieve and reuse an image that is likely to be used from a past image database. As a means for easily retrieving image data acquired by a measurement device without a load on an operator, for example, PTL 1 discloses a technique of retrieving an image, which is estimated to be important for an operator, from images stored in a database in an SEM device. In this disclosure, a technique has been proposed in which an “importance” score is created based on data in which various operation commands executed at the time of observation are recorded, such as automatic focus, luminance adjustment, and stage movement, and the score is assigned to acquired image data, thereby narrowing down image data that matches the importance at the time of image retrieval.

However, in the method disclosed in PTL 1, when collecting new training image data corresponding to a new experimental series, there is no appropriate image in the stored database. In the end, it is necessary to manually obtain training image data piece by piece. Therefore, an issue of reducing the burden on the operator related to the collection of new training image data cannot be coped with the method disclosed in PTL 1.

### CITATION LIST

### Patent Literature

PTL 1: JP2012-74187A

### SUMMARY OF INVENTION

### Technical Problem

An object of the present disclosure is to provide a charged particle beam device and a method for outputting image data of interest, which has a function of semi-automatically generating training image data in sample observation that uses the charged particle beam device, using the training image data to configure a feature identifier for automatically recognizes an observation visual field, and executing automatic imaging based on the feature identifier.

### Solution to Problem

An example of a charged particle beam device according to the invention includes:
a sample stage configured to move a sample;
an imaging unit configured to acquire observation image data of the sample;
an output unit configured to digitalize an operating status of the charged particle beam device and output operating status time series data;
a display unit configured to display a graphical user interface for displaying the observation image data and inputting an observation setting parameter; and
a computer system configured to store time series image data in which the observation image data is arranged in time series and execute arithmetic processing relating to the operating status time series data and the observation image data, in which
a time-point that matches a predetermined specific variation pattern is automatically determined based on the operating status time series data, and
observation image data corresponding to the time-point is acquired from the time series image data and is output as image data of interest.

An example of a method according to the invention is a method for outputting image data of interest by a charged particle beam device,
the charged particle beam device including
   a sample stage configured to move a sample,
   an imaging unit configured to acquire observation image data of the sample,
   an output unit configured to digitalize an operating status of the charged particle beam device and output operating status time series data,
   a display unit configured to display a graphical user interface for displaying the observation image data and inputting an observation setting parameter, and
   a computer system configured to store time series image data in which the observation image data is arranged in time series and execute arithmetic processing relating to the operating status time series data and the observation image data,
the method including:
a step of automatically determining a time-point that matches a predetermined specific variation pattern based on the operating status time series data; and
a step of acquiring observation image data corresponding to the time-point from the time series image data and outputting the observation image data as image data of interest.

### Advantageous Effects of Invention

According to the charged particle beam device and the method for outputting image data of interest according to the embodiments of the present disclosure, it is possible to semi-automatically generate training image data necessary for training a feature identifier for visual field recognition. As a result, the time and effort required for visual field search during sample observation can be significantly reduced, and a cross sectional image can be automatically captured.

### BRIEF DESCRIPTION OF DRAWINGS

FIG. 1 is a configuration diagram of a charged particle beam device according to a first embodiment.

FIG. 2A is a schematic diagram illustrating a relative positional relationship between a sample 20 and an inclination shaft in the first embodiment.

FIG. 2B is a schematic diagram illustrating a sample stage 17 in the first embodiment.

FIG. 3A is a flowchart illustrating a procedure of training a feature identifier 45.

FIG. 3B is a flowchart illustrating a procedure of generating training image data.

FIG. 4A is a schematic diagram illustrating a main GUI provided in the charged particle beam device.

FIG. 4B is a diagram illustrating a GUI used when generating training image data.

FIG. 4C is a diagram illustrating a GUI used when selecting an ROI 25.

FIG. 4D is a diagram illustrating a GUI used for setting an acquisition condition of an ROI including image 440.

FIG. 5 is a schematic diagram illustrating a method for extracting an image 523 of interest.

FIG. 6 is a flowchart illustrating an automatic imaging sequence for acquiring the ROI including image 440.

FIG. 7 is a schematic diagram illustrating a relationship between the ROI including image 440, a correct answer image 429, and an incorrect answer image 430.

FIG. 8 is a diagram illustrating a GUI used when training the feature identifier 45.

FIG. 9A is a flowchart illustrating an automatic imaging sequence.

FIG. 9B is a flowchart illustrating details of step S502 in FIG. 9A.

FIG. 9C is a flowchart illustrating details of step S505 in FIG. 9A.

FIG. 9D is a flowchart illustrating details of step S508 in FIG. 9A.

FIG. 10A is a diagram illustrating a GUI used for setting an automatic imaging condition.

FIG. 10B is a diagram illustrating a main GUI simultaneously displayed when setting an automatic imaging condition.

FIG. 11 is a diagram illustrating a GUI for instructing execution of an automatic imaging sequence.

FIG. 12 is a schematic diagram illustrating a sample cross section observation result at a high magnification.

FIG. 13A is a schematic diagram illustrating an operation of the sample stage 17 of a charged particle beam device according to a second embodiment.

FIG. 13B is a schematic diagram illustrating the sample stage 17 in FIG. 13A rotated by 90 degrees around a Z axis.

FIG. 14 is a flowchart illustrating details of step S508 according to a third embodiment.

FIG. 15 is a schematic diagram of a metal structure to be observed in a fourth embodiment.

### DESCRIPTION OF EMBODIMENTS

For example, in the development of a semiconductor device, when performing cross section observation of a processing pattern in a series of experimental series, a process is assumed in which a process engineer and an SEM operator perform first test observation together, and match recognition of a processing pattern shape to be observed and a mark pattern for finding an observation portion thereof while observing an actual sample (advance observation). When information at that time is converted into data, information on a region of interest (ROI) focused by the process engineer is included therein.

In an exemplary charged particle beam device of the present disclosure, a screen being observed in advance observation or the like is recorded as “time series image data” such as a moving image, “time series data on an operating state” of a device such as sample stage coordinates and an observation magnification is recorded simultaneously, and the time series image data and the time series data on an operating state are analyzed in combination, thereby semi-automatically generating training image data necessary for training a feature identifier for visual field recognition.

Specifically, an exemplary charged particle beam device of the present disclosure includes: an imaging unit configured to acquire image data of a sample at a predetermined magnification by irradiating a sample with a charged particle beam; a computer system configured to execute, by using the image data, arithmetic processing for visual field search when acquiring the image data; and a display unit configured to display a graphical user interface (GUI) for inputting a setting parameter for the visual field search. The imaging unit includes a sample stage that is capable of moving the sample by at least two drive axes, and that is capable of moving an imaging visual field correspondingly to position information of the sample obtained by the computer system. The computer system records an observation image, which is displayed on the display unit, as the “time series image data” that is moving image data or an image set obtained by continuously imaging at a fixed time interval, and simultaneously records the “time series data on an operating state” of the device. Further, the computer system calculates, from a specific variation pattern set in advance in the time series data on an operating state, an event time-point estimated to be focused by the operator and extracts, as an image of interest, a plurality of pieces of image data matching the event time-point from the time series image data. Further, the computer system records information on position coordinates of an ROI selected by the operator from the image of interest, an observation magnification, and the like. Based on the information, the sample stage is moved to the position coordinates of the ROI, and a plurality of images of the ROI are acquired under a plurality of conditions in which the observation magnification, an inclination angle of the sample stage, and the like are different. The computer system cuts out a predetermined range from the image of the ROI to generate training image data, and generates a feature identifier using the training image data. With respect to newly input image data, the feature identifier performs processing of outputting position information on one or more ROIs present on the image.

Hereinafter, embodiments of the present disclosure will be described in more detail, but the disclosure contents of the respective embodiments are not limited to the following description, and any configuration in which the elemental technologies disclosed or suggested in each embodiment are appropriately combined within the scope of knowledge of a person skilled in the art is also included in the scope of the present embodiment.

### First Embodiment

A first embodiment proposes an automatic observation method for a sample in which a function of semi-automatically generating training image data including an ROI to be observed is implemented in a charged particle beam device in which a scanning electron microscope (SEM) is an imaging device, and an automatic recognition function for a visual field configured thereby is used.

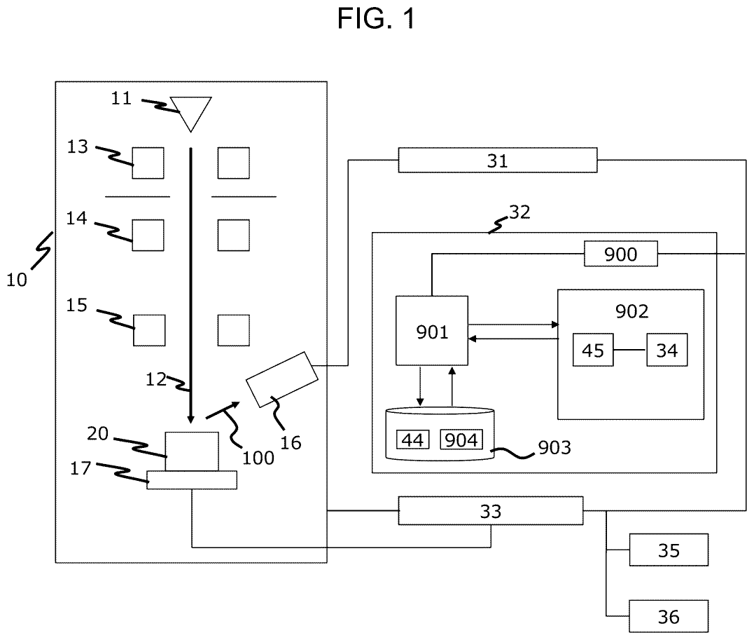

FIG. 1 illustrates a configuration diagram of a scanning electron microscope according to the first embodiment. A scanning electron microscope 10 of the first embodiment is an example of a charged particle beam device, and is, for example, a field emission scanning electron microscope (FE-SEM). The scanning electron microscope 10 can execute a method of outputting image data of interest described in the embodiment.

As an example, the scanning electron microscope 10 includes an electron gun 11, a focusing lens 13, a deflection lens 14, an objective lens 15, a secondary electron detector 16, a sample stage 17, an image forming unit 31, a control unit 33, a display unit 35, and an input unit 36, and further includes a computer system 32 for executing arithmetic processing required for a visual field search function of the embodiment. Hereinafter, each component will be described.

The electron gun 11 irradiates a sample with an electron beam (charged particle beam). The electron gun 11 includes a radiation source that emits an electron beam 12 accelerated by a predetermined acceleration voltage. The emitted electron beam 12 is focused by the focusing lens 13 and the objective lens 15, and is irradiated onto a sample 20. The deflection lens 14 deflects the electron beam 12 by a magnetic field or an electric field. With the deflection, a surface of the sample 20 is scanned by the electron beam 12.

The sample stage 17 has a function of moving the sample 20 parallelly to a predetermined drive shaft or inclining and/or rotating the sample 20 around a predetermined drive shaft, in order to move an imaging visual field of the scanning electron microscope 10, and includes actuators of a motor and a piezoelectric element for this purpose.

The secondary electron detector 16 is an E-T detector or a semiconductor detector that includes a scintillator, a light guide, and a photomultiplier tube, and detects secondary electrons 100 emitted from the sample 20 irradiated with the electron beam 12. A detection signal output from the secondary electron detector 16 is transmitted to the image forming unit 31. The secondary electron detector 16 may be provided with a backscattered electron detector configured to detect backscattered electrons and a transmission electron detector configured to detect transmitted electrons.

The image forming unit 31 includes an AD converter configured to convert a detection signal transmitted from the secondary electron detector 16 into a digital signal, and an arithmetic unit (not shown) configured to form an observation image of the sample 20 based on the digital signal output from the AD converter. As the arithmetic unit, for example, a micro processing unit (MPU) or a graphic processing unit (GPU) is used. The observation image formed by the image forming unit 31 is transmitted to the display unit 35 and displayed, or transmitted to the computer system 32 and subjected to various types of processing.

As described above, the scanning electron microscope 10 includes the electron gun 11, the secondary electron detector 16, and the image forming unit 31. The electron gun 11, the secondary electron detector 16, and the image forming unit 31 (image constructor) constitute an imaging unit in the embodiment. When such an imaging unit is used, an image using an electron beam (charged particle beam) can be acquired.

The computer system 32 includes an interface part 900 for inputting and outputting data and commands from and to the outside, a processor 901 (for example, a central processing unit (CPU)) configured to execute various types of arithmetic processing on given information, and a memory 902 and a storage 903 that constitute a storage unit.

The storage 903 is implemented by, for example, a hard disk drive (HDD) or a solid state drive (SSD), and stores software 904 constituting a visual field search tool of the embodiment and a training data DB (database) 44. The software 904 of the embodiment is a visual field search tool. In one example, when the processor 901 executes the software 904, a feature identifier 45 and an image processing unit 34 are implemented as functional blocks in cooperation with the memory 902.

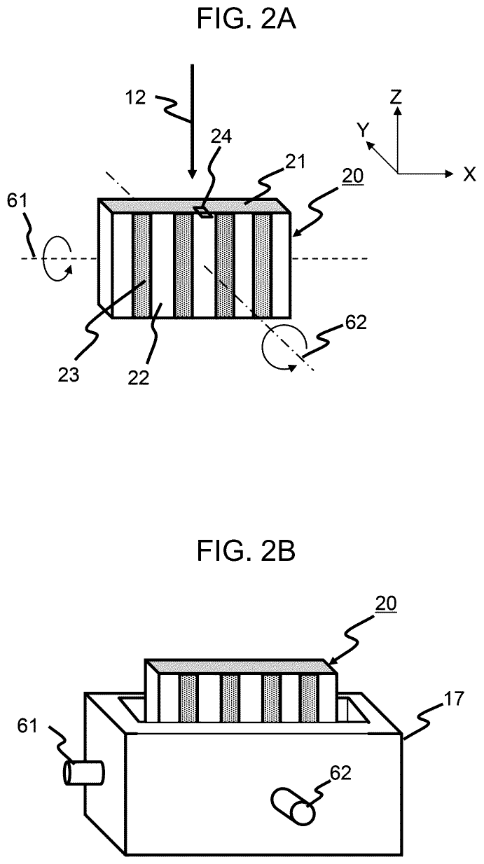

The feature identifier 45 extracts a mark pattern 23 (described later with reference to FIG. 2A and the like) for visual field search from input image data. For example, the feature identifier 45 determines whether the mark pattern 23 is present at each position of the image data, and outputs a position at which it is determined that the mark pattern 23 is present (or a position at which it is determined that a probability of presence of the mark pattern 23 in the image data is highest). The image processing unit 34 refers to position information of the sample stage 17 to calculate position coordinates of the mark pattern 23 base on a position of a detected mark pattern on the image.

The memory 902 illustrated in FIG. 1 represents a state where functional blocks constituting the software 904 are deployed in a memory space. When executing the software 904, the processor 901 executes functions of the respective functional blocks developed in the memory space.

The feature identifier 45 is a trained model generated by machine learning, and is trained by using image data of the mark pattern 23 stored in the training data DB 44 as training data. When new image data is input to the feature identifier 45, a position of the learned mark pattern on the image data is determined, and the position of the mark pattern in the new image data (center coordinates of the mark pattern in the following examples) is output. The output center coordinates are used for specifying a region of interest (ROI) at the time of visual field search. Further, various types of position information calculated from the center coordinates are transmitted to the control unit 33 and used for drive control of the sample stage 17.

The image processing unit 34 performs processing such as calculation and/or evaluation of image sharpness when automatically executing edge line detection, focus adjustment, astigmatism correction, and the like of a wafer surface based on image processing in a cross sectional image of a sample cross section directly facing the visual field.

The control unit 33 is an arithmetic unit configured to control the components in FIG. 1 and process or transmit data generated by the components, and includes a CPU and an MPU, for example. The input unit 36 is a device configured to receive an input of an observation condition for observing the sample 20 and receive an input of an instruction such as execution or stop of the observation. For example, the input unit 36 may be implemented by a keyboard, a mouse, a touch panel, a liquid crystal display, or a combination thereof. On the display unit 35, a graphical user interface (GUI) constituting an operation screen for an operator or a captured image (observation image data) is displayed.

Next, a relative positional relationship between the sample 20 to be observed and a drive shaft of the sample stage 17 will be described with reference to FIG. 2A. FIG. 2A is a perspective view of a wafer sample, which is an example of an object to be observed by the charged particle beam device according to the embodiment.

In FIG. 2A, the sample 20 is a coupon sample obtained by cleaving a wafer, and has a fracture surface 21 and an upper surface 22 on which a processing pattern is formed. The sample 20 is manufactured through a manufacturing process of a semiconductor device and a process development process. A fine structure is formed on the fracture surface 21. In many cases, an imaging portion intended by the operator of the charged particle beam device lies in the fracture surface 21.

The mark pattern 23 is formed on the upper surface 22. The mark pattern 23 is a shape or structure having a size larger than the fine structure described above, that is, a pattern that can be used as a mark at the time of the visual field search. As the mark pattern 23, for example, a characteristic shape marker for identifying a chip processed region on a wafer or a processing pattern including label information can be used.

Orthogonal axes of XYZ shown in FIG. 2A are coordinate axes indicating a relative positional relationship with respect to the electron beam 12 of the sample 20. A traveling direction of the electron beam 12 is the Z axis, a direction parallel to a first inclination shaft 61 of the sample stage 17 is the X axis, and a direction parallel to a second inclination shaft 62 is the Y axis. In the embodiment, the sample 20 is placed on the sample stage 17 such that a longitudinal direction thereof is parallel to the X axis.

When observing a fine shape of the fracture surface 21, the electron beam 12 is irradiated substantially perpendicularly to the fracture surface 21, and a region of a cross-section observation visual field 24 is observed. However, the manually cleaved fracture surface 21 is often not completely orthogonal to the upper surface 22. When the operator places the sample 20 on the sample stage 17, a mounting angle thereof is not necessarily the same every time.

Therefore, the first inclination shaft 61 and the second inclination shaft 62 are provided on the sample stage 17 as an angle adjustment shaft for making the fracture surface 21 orthogonal to the electron beam 12. The first inclination shaft 61 is a drive shaft for rotating the sample 20 in a YZ plane. Since a longitudinal direction of the fracture surface 21 is an X-axis direction, a rotation angle of the first inclination shaft 61 is adjusted when adjusting the inclination angle of a so-called tilt image in which the sample 20 is observed while being tilted from the oblique direction. Similarly, the second inclination shaft 62 is a drive shaft for rotating the sample 20 in a XZ plane. When the visual field is located directly facing the fracture surface 21, an image can be rotated around an axis in an up-down direction (Y-axis direction) passing through a visual field center by adjusting a rotation angle of the second inclination shaft 62.

A configuration of the sample stage 17 will be described with reference to FIG. 2B. As illustrated, the sample 20 is held and fixed on the sample stage 17. The sample stage 17 is provided with a mechanism for rotating a placement surface of the sample 20 around the first inclination shaft 61 and the second inclination shaft 62, and the rotation angle is controlled by the control unit 33. Although not illustrated, the sample stage 17 illustrated in FIG. 2B includes an X drive shaft, a Y drive shaft, and a Z drive shaft for independently moving the sample placement surface in the XYZ directions, and a rotation shaft for rotating the sample placement surface around the Z drive shaft. A scanning region (i.e., the visual field) of the electron beam 12 can be moved in the longitudinal direction, a transverse direction and a height direction of the sample 20, and can also be rotated. Moving distances of the X drive shaft, the Y drive shaft, and the Z drive shaft are also controlled by the control unit 33.

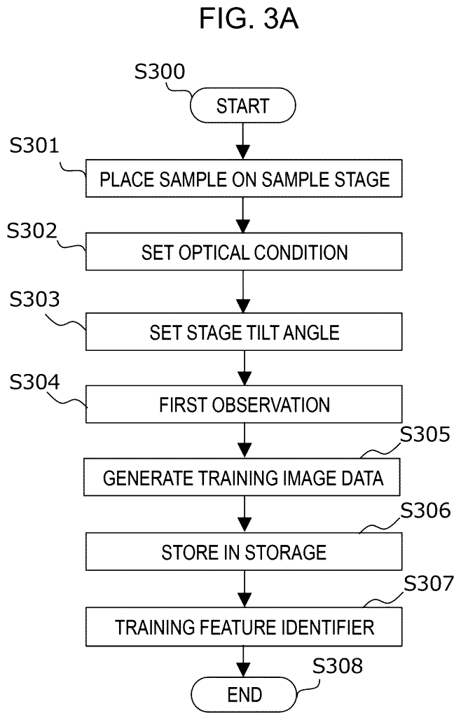

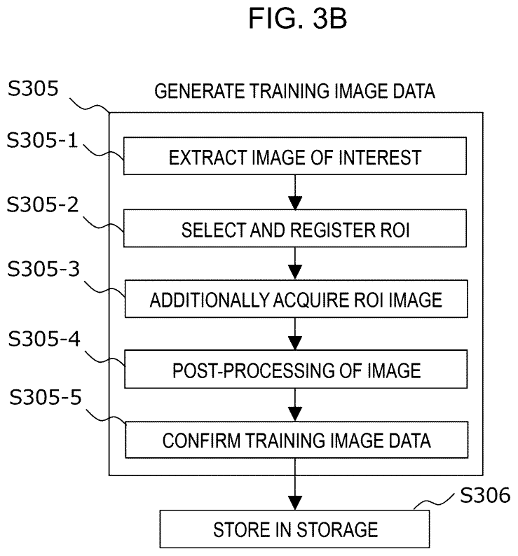

In the embodiment, the feature identifier 45 for automatically recognizing the mark pattern 23 in the tilt image observed by tilting the sample 20 from an oblique direction is configured, and high-magnification observation is executed at a position spaced apart from the mark pattern 23 serving as a reference point by a predetermined distance. Next, referring to FIGS. 3A, 3B, 4A, 4B, 4C, 4D, 5, 6, 7, and 8, a procedure of training of the feature identifier 45 according to the embodiment will be described.

In the embodiment, in order to execute the automatic visual field search and automatic imaging in which the automatic visual field search is used, the feature identifier 45 for detecting the mark pattern 23 is configured. A flowchart in FIG. 3A shows a workflow executed by the operator when configuring the feature identifier 45.

After the processing in FIG. 3A is started (step S300), the sample 20 is placed on the sample stage 17 in the charged particle beam device illustrated in FIG. 1 (step S301). Next, an optical condition for capturing an image serving as training data such as an acceleration voltage and a magnification is set (step S302).

Thereafter, a tilt angle of the sample stage 17 is set (step S303), and first observation is performed (step S304). The first observation refers to first observation work in which the operator confirms a mark pattern, a processing pattern desired to be finally observed, or the like. In some cases, the operator performs the first observation alone, or in some cases, an SEM operator is informed of a region of interest or the like while viewing an observation screen, in the presence of a process engineer. By step S304, information necessary for generating training image data is acquired. Subsequently, the training image data is generated by the execution of step S305, and the generated training image data is stored in the storage 903 (step S306).

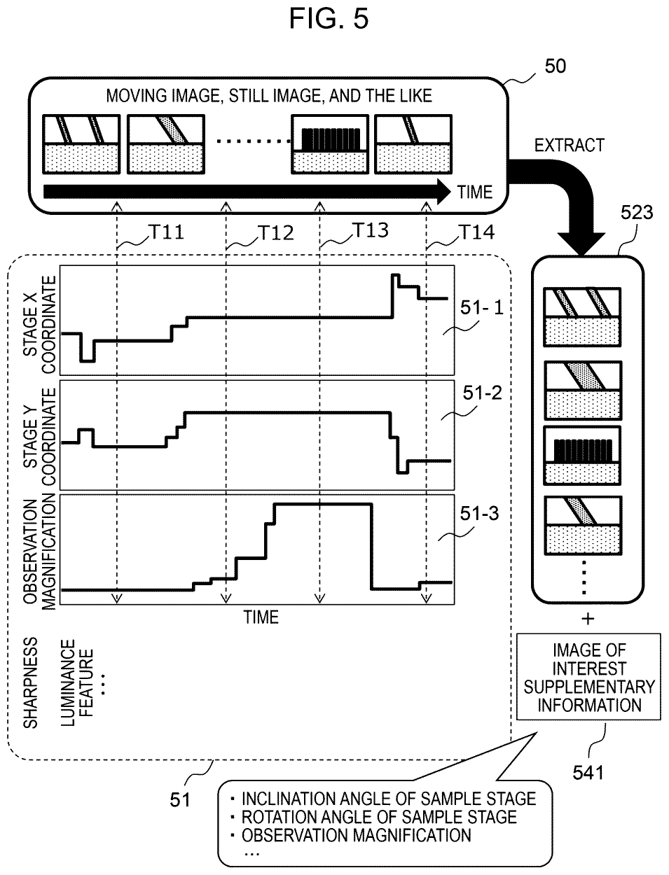

A workflow illustrating details of step S305 is shown in FIG. 3B. Based on the data obtained by the first observation in step S304, extraction of an image 523 of interest (described later in relation to FIG. 5 and the like) is executed by automatic processing (step S305-1). Next, selection and registration of an ROI by the operator are executed based on the image 523 of interest (step S305-2), and based on the information, additional acquisition of an ROI image is executed by automatic processing (step S305-3). Thereafter, in order to acquire appropriate training image data based on the acquired ROI image, image post-processing is executed (step S305-4). Finally, confirmation of the generated training image data is performed by the operator (step S305-5), and the training image data that passes the confirmation is stored in the storage 903 (step S306). Details of each step will be described later.

The procedure of training of the feature identifier 45 described above will be described in more detail with reference to drawings of a GUI.

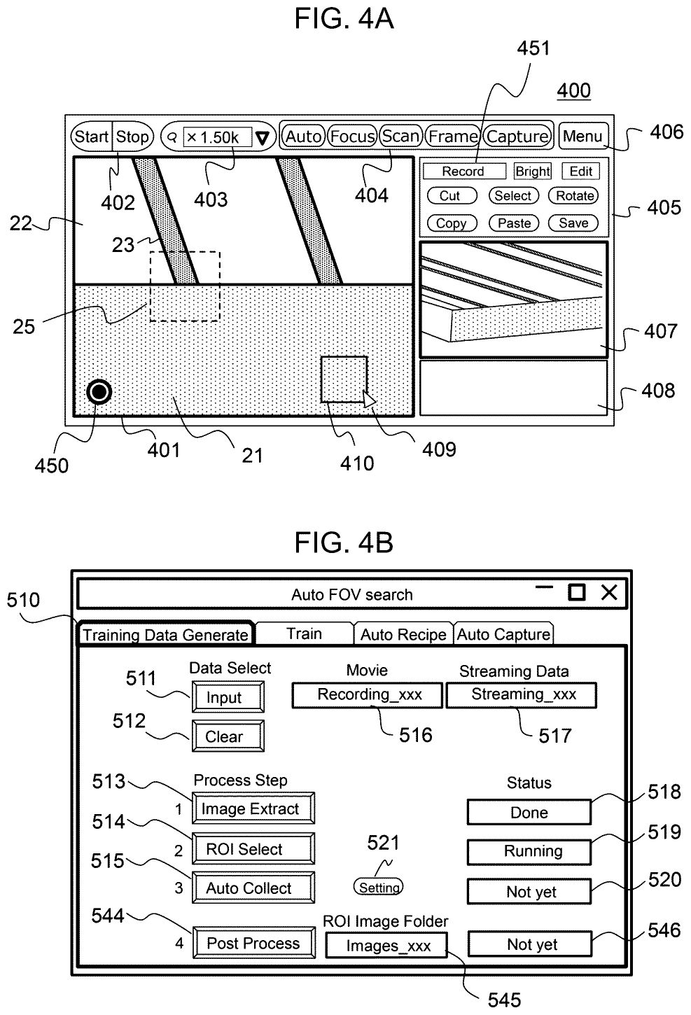

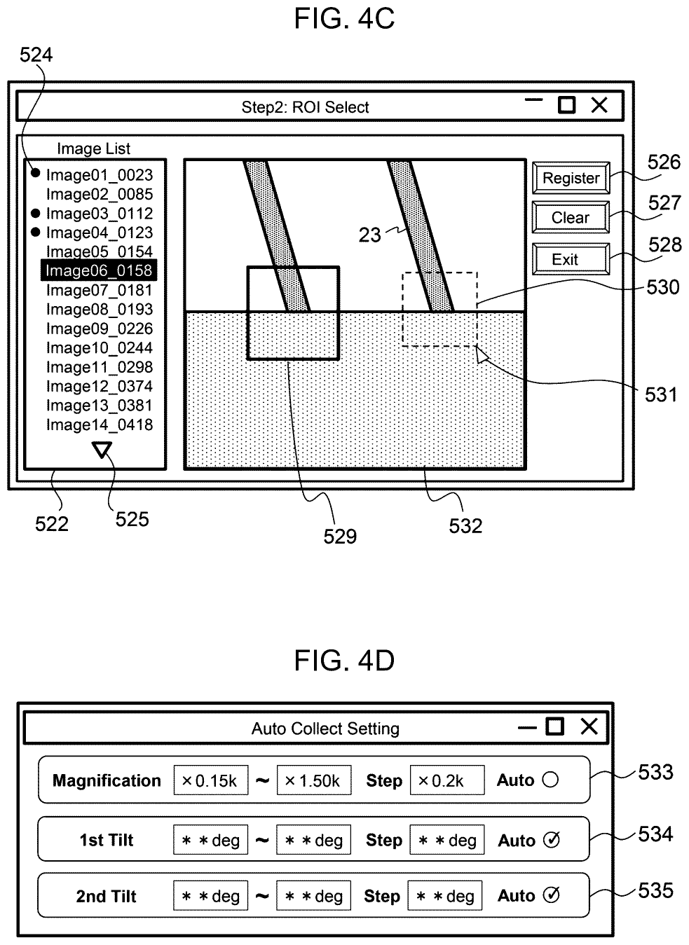

FIG. 4A illustrates a main GUI 400 displayed on the display unit 35 of the charged particle beam device according to the embodiment. The main GUI in FIG. 4A and similar GUIs in other drawings are graphical user interfaces for inputting an observation setting parameter.

An example of a tilt image is displayed on the main GUI. The main GUI illustrated in FIG. 4A includes, as an example, a main screen 401, an operation start and stop button 402 for instructing start and stop of operation of the charged particle beam device, a magnification adjustment field 403 for displaying and adjusting an observation magnification, a select panel 404 in which an item button for selecting a setting item of an imaging condition is displayed, an operation panel 405 for adjusting image quality and the stage, a menu button 406 (“Menu”) for calling another operation function, a sub-screen 407 for displaying an image of a wider visual field than in the main screen 401, and an image list region 408 for displaying a thumbnail image of a captured image. The GUI described above is merely a configuration example, and a GUI in which items other than those described above are added or the items are replaced with other items can also be adopted.

At the start of step S304, the operator presses a recording button 451 (“Record”) in the operation panel 405, and starts recording of time series image data 50 being observed (described later in relation to FIG. 5 and the like) and operating status time series data 51 of the device (described later in relation to FIG. 5 and the like). The time series image data 50 is data in which observation image data is arranged in time series, and is stored in the computer system 32. As will be described later, the computer system 32 can execute arithmetic processing relating to the operating status time series data 51 and the observation image data.

As an example, FIG. 4A illustrates a state where a tilt image is displayed on the main screen 401 being observed, and the tilt image includes the fracture surface 21, the upper surface 22, and the mark pattern 23. In step S304, the operator confirms the mark pattern 23 serving as a starting point of an observation portion while viewing the tilt image, moves the sample stage 17 based on the confirmation, inclines the sample stage 17 such that the fracture surface 21 of the sample 20 directly faces an observation surface, and observes a processing pattern desired to be acquired. When the first observation in step S304 is completed, the operator presses the recording button 451 again to complete the recording of data. During the recording of the data, a recording mark 450 is displayed at a left corner of the main screen 401, and when the recording of the data is completed, the display of the recording mark 450 disappears.

After step S304 (first observation) is completed, step S305 (generation of training image data) is performed. FIG. 4B illustrates a configuration example of a GUI screen used by the operator in step S305. In a case of displaying the GUI in FIG. 4B from a state where the GUI in FIG. 4B is not displayed, one option of “automatic visual field search” (“Auto FOV search”) is selected from select buttons displayed by pressing the menu button 406 in FIG. 4A, and accordingly a training data generation tool screen illustrated in FIG. 4B is popped up. In the operation of step S305, a tab 510 of “training data generation” (Training Data Generate) is selected.

In the training data generation tool screen illustrated in FIG. 4B, the operator presses an input button 511 (“Input”) in a data selection region (“Data Select”), and selects the time series image data 50 stored in the storage 903 in step S304 and the operating status time series data 51. Selected file are displayed in a time series image data name display field 516 and an operating status time series data name display field 517. If another file is desired to be selected, a clear button 512 (“Clear”) is pressed to clear the registered file, and then an appropriate file is selected again.

Subsequently, in the process of step S305-1 (extraction of an image of interest), when the operator presses an image extraction button 513 (“Image Extract”), the time series image data 50 and the operating status time series data 51 are automatically acquired. As a result, the image 523 of interest that is estimated to be focused on by the operator is displayed, and the operating status time series data 51 is output. As described, in step S305-1, the processor 901 functions as an output unit that digitizes an operating status of the scanning electron microscope 10 and outputs the operating status time series data 51.

When the process of extracting the image of interest in step S305-1 is completed, a message “completed” (“Done”) is displayed in a status display field 518 indicating the operating status.

FIG. 5 schematically illustrates a data analysis processing operation executed by the computer system 32 in step S305-1 of extracting an image of interest. In an upper portion of FIG. 5, the time series image data 50 is illustrated, and a state is shown that many observation images are stored along a time axis. When the time series image data 50 is a moving image format, the time series image data is an image data set. For example, in case of 30 frames per second (fps), 30 images are included per second.

When the time series image data 50 is moving image data, the time series image data 50 can be efficiently processed using a known moving image processing program or the like. When the time series image data 50 is a collective data set of still image data, the moving image processing is not necessary, and the processing is simplified.

In a lower portion of FIG. 5, the operating status time series data 51 is illustrated. Here, time series data 51-1 of stage X coordinate, time series data 51-2 of stage Y coordinate, and time series data 51-3 of an observation magnification are illustrated. The operating status time series data 51 is not limited to that illustrated in the drawing, and may be data including at least one of the following.
Position information of sample stage 17
Inclination angle information of sample stage 17
Rotation angle information of sample stage 17
Observation magnification information
Current information of objective lens 15
Stigma current information
Acceleration voltage information of charged particle beam
Evaluation value of in-observation image

By using the operating status time series data 51, various patterns for extracting an image of interest can be defined.

In particular, when the operating status time series data 51 includes the evaluation value of an in-observation image, the evaluation value can be defined to include at least one of the following.
Sharpness calculated by high-frequency component analysis of image
Luminance feature calculated based on luminance distribution of image

By using the operating status time series data 51, it is possible to extract an image having high sharpness or an image having appropriate luminance distribution, and to perform subsequent image processing with higher accuracy.

In the computer system 32, a specific variation pattern (event of interest) is set in advance for the operating status time series data 51. The computer system 32 automatically determines a time-point, which matches the event of interest, based on the operating status time series data 51.

In the embodiment, as requirements of the event of interest, two requirements are set: (1) watching for a certain period of time or longer; and (2) increasing the magnification at the same position. For (1) the watching event lasting for a certain period of time or longer, the requirement was defined to be that the operator maintained the position of the stage and the observation magnification without any changes for a certain period of time. This event corresponds to a pattern for which the sample stage is stopped for a predetermined period of time (first time) and the magnification in the predetermined period of time (first time) is fixed. On the other hand, for (2) the magnification increase event at the same position, the requirement was defined to be that the operator increased only the observation magnification without changing the X and Y coordinates of the stage at all. This event corresponds to a pattern for which the sample stage 17 is stopped for a predetermined period of time (second time) and the magnification is changed in the predetermined period of time (second time). The first time and the second time may be the same time or different times.

Variation patterns satisfying the event requirements (1) and (2) are retrieved from the operating status time series data 51 and examples of determined time-points thereof are time-points T11, T12, T13, T14 shown in FIG. 5. The time-point T11 and time-point T13 correspond to (1) the watching event lasting for a certain period of time or longer, and the time-point T12 and the time-point T14 correspond to (2) the magnification increase event at the same position. FIG. 5 shows an outline, and time-points indicated by the time-points T11, T12, T13, and T14 are not precise.

The computer system 32 acquires, as image data of interest, observation image data corresponding to the time-points T11, T12, T13, and T14 from the time series image data 50, and outputs the observation image data. The image data of interest is stored in the storage 903 as the image 523 of interest, for example. In addition, image-of-interest supplementary information 541 in which a time-point of the event, coordinates of the stage, tilt angle information, the observation magnification, and the like are recorded is stored in the storage 903 in a CSV format file as device status data supplementary to each image 523 of interest.

By defining such an event, an appropriate image 523 of interest can be acquired. In the embodiment, both a time-point matching (1) the watching event lasting for a certain period of time or longer and a time-point matching (2) the magnification increase event at the same position are extracted. Alternatively, only one may be extracted.

Returning to FIG. 4B, the process of step S305-2 (selection and registration of ROI) will be described. In step S305-2, the ROI is selected using the image 523 of interest extracted in step S305-1. When the operator presses an ROI selection button 514 (“ROI Select”), an ROI selection GUI shown in FIG. 4C is displayed. In the ROI selection GUI, an image name list 522 of the image 523 of interest is displayed on the left side of the screen.

When any image-of-interest name in the image name list 522 is selected with the mouse, the image name is highlighted, and the selected image of interest is displayed on a main screen 532. With respect to the image 523 of interest displayed on the main screen 532, the operator selects a region, which is recognized by the operator as the ROI, by a mouse operation (for example, selects a region including the mark pattern 23 (that is, the ROI) by using a pointer 531 and a selection tool 530).

Thereafter, a register button 526 (Register) is pressed to register information of the ROI. In this manner, the scanning electron microscope 10 receives the designation of the ROI in the image of interest through the ROI selection GUI. The registered ROI is displayed in a thick frame as indicated by a registered ROI 529. Here, when the registration is executed, image data of the registered ROI 529 is stored in the storage 903, and ROI supplementary information is stored in the storage 903 as information supplementary to the ROI.

The ROI supplementary information includes stage coordinates in the real space of the ROI, an inclination angle of the stage, a size of the ROI, an observation magnification, and the like, and is stored as a CSV format file. For example, the ROI supplementary information may be the same as the image-of-interest supplementary information 541 of the image of interest including the ROI, and may be information obtained by correcting the image-of-interest supplementary information 541 in accordance with the position or the like of the ROI in the image of interest.

The ROI supplementary information may include at least one of the following.
Inclination angle information of sample stage 17
Rotation angle information of sample stage 17
Observation magnification information

In this way, a condition in which each ROI is imaged is stored in supplement to the ROI, and re-imaging of the ROI and a periphery thereof is facilitated.

In this manner, the scanning electron microscope 10 stores the image data and the ROI supplementary information of the ROI 529. According to such a configuration, when the operator designates any ROI, the supplementary information can be automatically stored, and the work efficiency is improved. In particular, when the ROI supplementary information includes the position information of the sample stage 17 corresponding to the ROI, the position information of the sample stage 17 is automatically stored in accordance with the designation of the ROI, and the work efficiency is further improved.

When a wrong portion is registered, the ROI can be selected with the pointer 531, and the registration can be removed by a clear button 527 (“Clear”). For an image of interest for which the ROI selection and registration processing are performed, a processed mark 524 is displayed in the image name list 522. When there are many images 523 of interest and the images of interest cannot be fully displayed at a time in the image name list 522 on the GUI, the list can be scrolled through using a scroll button 525.

When the operator presses an end button 528 (“Exit”) after all desired ROIs are selected and registered, the GUI in FIG. 4C is closed. In conjunction with this, “completed” (“Done”) is displayed in a status display field 519 in FIG. 4B, and the ROI selection and registration process of step S305-2 are ended.

Returning to FIG. 4B, the process of step S305-3 (additional acquisition of ROI image) will be described. In step S305-3, an additional ROI image is automatically acquired using ROI information registered in step S305-2 and an automatic imaging function. When a setting button 521 (“Setting”) on the GUI in FIG. 4B is pressed, a setting GUI in FIG. 4D is displayed.

In order to construct the feature identifier 45 having high accuracy, it is desirable to prepare training image data acquired under various conditions. In the setting GUI in FIG. 4D, a setting panel 533 of an imaging magnification, a setting panel 534 of a first tilt angle of the sample stage (a rotation angle around the first inclination shaft 61 in FIG. 2B), and a setting panel 535 of a second tilt angle of the sample stage (a rotation angle around the second inclination shaft 62 in FIG. 2B) are provided.

The operator inputs a start value and an end value and a step value therebetween in each setting panel. For example, if the start value of the imaging magnification is set to “'0.1 k”, the end value is set to “×1.0 k”, and the step value is set to “0.1 k”, a total of 10 imaging magnification conditions can be set, with an interval of 0.1 from ×0.1 k to ×1.0 k. The unit “k” represents “kilo”, that is, 1000.

Similarly, if a set value of the first tilt angle (the rotation angle around the first inclination shaft 61 in FIG. 2B) is set at an interval of 1° from 1° to 5°, five angle conditions can be set. If the second tilt angle (the rotation angle around the second inclination shaft 62 in FIG. 2B) is fixed at 0°, both the start value and the end value are set to 0°.

When the above setting is performed, a condition in which the imaging magnification and the tilt angle are combined is generated. In this example, a total of 10× 5=50 imaging conditions are set. The imaging conditions are stored in the storage 903 as additional imaging conditions. That is, the additional imaging condition in the embodiment includes one or more combinations of the imaging magnification, the first tilt angle, and the second tilt angle. When automatic radio buttons (“Auto”) of the setting panels 533, 534, and 535 are checked, default conditions set in advance for the corresponding setting panels are applied. When there is no need to change the settings each time, the work load of the operator can be reduced.

Returning to the GUI in FIG. 4B again after the setting of the imaging conditions is completed, when the operator presses an automatic collection button 515 (“Auto Collect”), additional imaging of the ROI in step S305-3 is automatically performed.

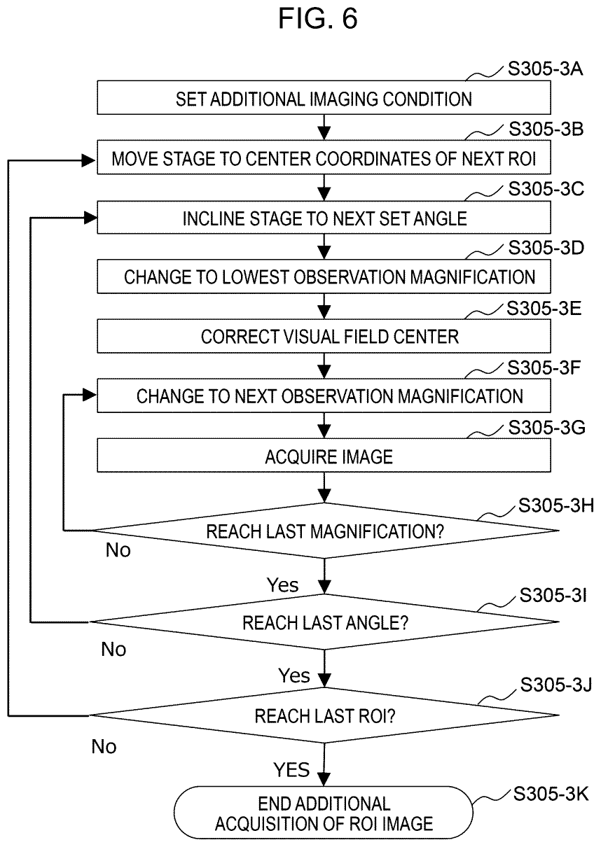

FIG. 6 illustrates a flowchart of additional acquisition of an ROI image. In step S305-3A, additional imaging conditions are stored using the setting GUI as described with reference to FIG. 4D. In step S305-3B, the sample stage 17 is moved to center coordinates of a next ROI (a first ROI when the step is first executed, for example, an ROI described at the head of a plurality of ROIs described in the ROI supplementary information). In this manner, the scanning electron microscope 10 uses the ROI supplementary information to move the sample stage 17 to a position where the ROI can be imaged.

In step S305-3C, the stage is inclined to a next set angle described in the additional imaging condition (a first set angle when the step is first executed, for example, a set angle described at the head of set angles described in the additional imaging condition). In step S305-3D, the observation magnification is set to a lowest magnification of the scanning electron microscope 10.

In step S305-3E, visual field center correction is performed based on an observation image of the lowest magnification. As illustrated in FIG. 4A, in the tilt image at the time of visual field observation, the upper surface 22 (wafer surface) of the sample and the fracture surface 21 are observed, and a boundary line thereof can be visually recognized as an edge line. In a visual field center correction method, the edge line is detected by image processing, actual position coordinates of the edge line are calculated based on position information of the edge line in the image and position information of the sample stage 17, and the sample stage 17 is moved such that the position coordinates of the edge line are the center of the visual field. As an image processing algorithm for detecting an edge line, for example, a straight line detection by Hough transform can be used. In order to further improve the detection accuracy, processing of a Sobel filter or the like may be performed, and pre-processing to emphasize the edge line may be performed.

In step S305-3F, the magnification condition is changed to a next magnification condition described in the additional imaging condition. Thereafter, in step S305-3G, an ROI including image 440 in which the ROI is captured at the visual field center is acquired. In step S305-3H, the imaging magnification is determined. It is determined whether a last magnification (for example, a highest magnification among magnifications described in the additional imaging condition) is reached. If the last magnification is not reached, the process returns to step S305-3F, a next magnification is set, and the processing of acquiring the ROI including image 440 is repeated.

If the last magnification is reached in step S305-3H, the process proceeds to step S305-31. In step S305-31, it is determined whether the set angle is a last angle (for example, a large angle among tilt angles described in the additional imaging condition). If the set angle is not the last angle, the process returns to step S305-3C, and after performing visual field center correction at the lowest magnification at the next set angle, the processing of acquiring the ROI including image 440 while changing the magnification is repeated.

In FIG. 6, in order to simplify the description, a loop of the angle (loop from step S305-3I to step S305-3C) is illustrated as a single loop. In reality, a loop is executed for each of the first tilt angle and the second tilt angle, forming a double loop.

When the last angle condition is reached in step S305-31, the process proceeds to step S305-3J. In step S305-3J, it is determined whether the ROI is the last ROI among ROIs described in the additional imaging condition. If the ROI is not the last ROI, the process returns to step S305-3B, and the processing of acquiring the ROI including image 440 under a plurality of conditions while changing the stage inclination and the magnification condition at the center coordinates of a next ROI is repeated.

In this manner, the scanning electron microscope 10 acquires additional image data of the ROI under a plurality of imaging conditions. The plurality of imaging conditions may include conditions under which one of the magnification, the inclination angle of the sample stage, and the rotation angle of the sample stage is different. When the plurality of imaging conditions are used, a possibility of acquiring an image in which the mark pattern 23 appears appropriately is increased.

When the last ROI is reached in step S305-3J, the additional acquisition processing of the ROI image ends (step S305-3K). When the above is completed, display in a status display field 520 is “completed” (“Done”) on the training data generation tool screen in FIG. 4B, and the process of additional acquisition of the ROI image of step S305-3 (FIG. 3B) is completed.

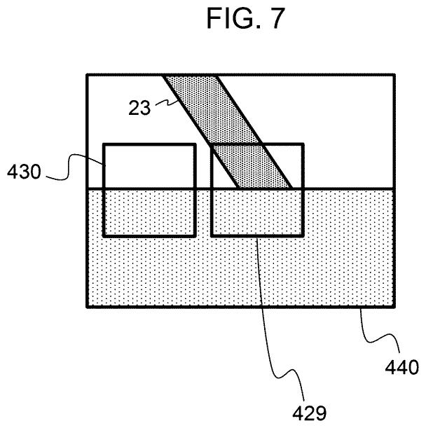

When step S305-3 is completed, the process proceeds to the image post-processing process in step S305-4 (FIG. 3B). The process of step S305-4 will be described with reference to FIGS. 7 and 4B.

FIG. 7 is a schematic diagram illustrating a relationship between the ROI including image 440 acquired by step S305-3 and a correct answer image 429 and an incorrect answer image 430 of training data used for configuring the feature identifier 45. In the embodiment, the feature identifier 45 is configured by a cascade classifier. In the cascade classifier, two types of image data sets, that is, a correct answer image including a target ROI and an incorrect answer image are used as training image data. In step S305-4, in the ROI including image 440, a region including the mark pattern 23 or a part thereof is stored as the correct answer image 429, and a region not including the mark pattern 23 or even a part thereof is stored as the incorrect answer image 430.

Returning to the GUI in FIG. 4B, the operation in step S305-4 will be described. When step S305-3 ends, a folder in which image data including many acquired ROI including images 440 is stored is displayed in an image folder display field 545.

If it is desired to use an image set other than the image sets additionally acquired in step S305-3, the image folder display field 545 is clicked to select an appropriate image folder.

Thereafter, when a post-processing button 544 (“Post Process”) is pressed, the regions of the correct answer image 429 and the incorrect answer image 430 are automatically clipped and processed as described with reference to FIG. 7, and are stored in the new training image data folder. The automatic cutout processing at this time can be appropriately designed based on a known technique. For example, each region may be specified by using an algorithm that does not depend on machine learning, or when a general feature identifier 45 based on machine learning can be used, the feature identifier 45 may be used. When an erroneous specification is made, since correction can be performed in the subsequent step S305-5, it is not essential to increase the specifying accuracy in step S305-4.

The correct answer image 429 and the incorrect answer image 430 are stored in different sub-folders. The same processing is performed on all ROI including images 440 acquired in step S305-4. When the processing is completed, the image post-processing process of step S305-4 is completed, and a status display field 546 on the GUI in FIG. 4B is “completed” (“Done”).

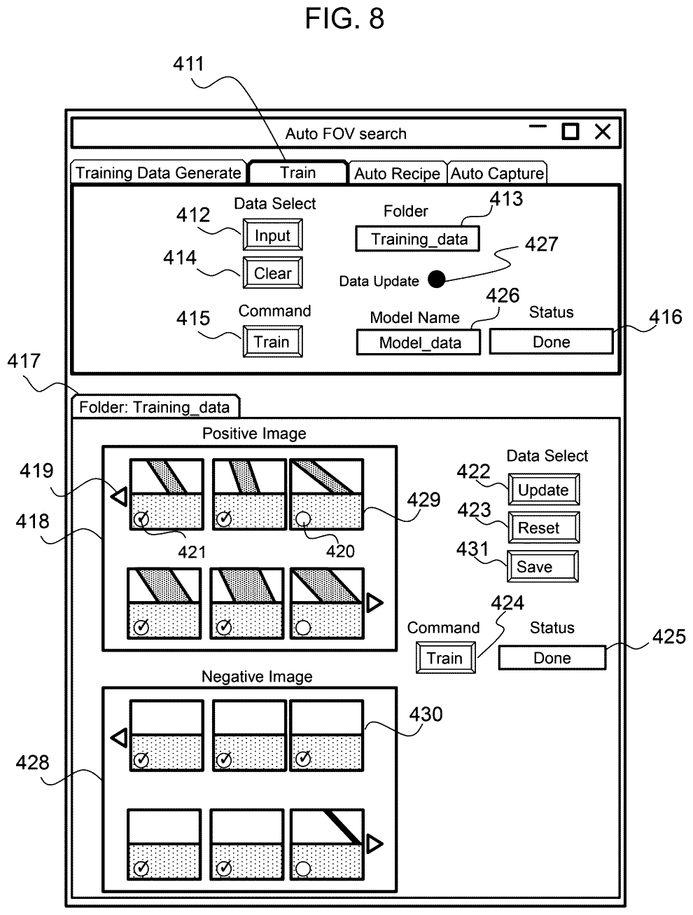

Subsequently, the process proceeds to the training image data confirmation process in step S305-5 (FIG. 3B). FIG. 8 illustrates a configuration example of a GUI screen used in the process of step S305-5. In order to display the GUI in FIG. 8 from a state where the screen is not displayed, the “automatic visual field search” is selected from the select buttons displayed by pressing the menu button 406 in FIG. 4A, and accordingly a training tool screen shown in FIG. 8 is popped up.

In the operation of step S305-5, a training tab 411 (“Train”) is selected. The operator presses an input button 412 (“Input”) of data selection (“Data Select”) and selects a folder in which a training image data set generated in step S305-4 is stored. A name of the selected folder is displayed in an image folder display field 413. In order to change the designation of the image folder, a clear button 414 (“Clear”) is pressed and the selection operation is performed again.

When the folder of the training image data is selected, a training image data tab 417 (“Folder: Training_data”) is displayed in a lower section of the GUI, the correct answer image 429 is displayed on an image display screen 418, and the incorrect answer image 430 is displayed on an image display screen 428. Images that cannot be fully displayed on the image display screens 418 and 428 can be scrolled through using a scroll button 419.

Each piece of training image data is provided with a check mark input field 420. In the initial setting, a check mark 421 is assigned to all images. The operator confirms the displayed training image data, and if there is any inappropriate image, removes its check mark 421 by operating the mouse.

When the confirmation ends, the operator presses an update button 422 (“Update”) to update the training image data. At this time, an update display button 427 (“Data Update”) in an upper section of the GUI blinks, and the operator is informed that the data update is performed. When a plurality of pieces of the training image data are to be re-selected, a reset button 423 (“Reset”) can be pressed to initialize the check mark input field 420 to return to the state where the check mark 421 is assigned to all images.

When the update button 422 is pressed, all images to which the check mark 421 is assigned at that time are copied as training image data, and are temporarily stored in the training data DB 44. At this time, since contents of the original training image data set are maintained without being changed from the state immediately after pressing the input button 412, no data corruption occurs when the data is reused later. On the other hand, when it is desired to store the updated training image data set as a new data set, a save button 431 (“Save”) can be pressed and the updated training image data set can be stored as a data set with a new name.

Through the above processes, the training image data confirmation process in step S305-5 is completed, and accordingly, a process of storing the training data in the storage in step S306 is also completed (FIG. 3B). If there is no particular need to update the training image data displayed by pressing the input button 412 of data selection, the processes of step S305-5 and step S306 are completed as it is.

Subsequently, the process of step S307 (training of the feature identifier) will be described (FIG. 3A). When the setting of the training image data ends, the operator starts training by pressing a training button 415 (“Train”) in the upper section of the GUI or a training button 424 (“Train”) in the lower section of the GUI in FIG. 8. A status display field cell 416 and a status display field cell 425 are displayed next to the training button 415 and the training button 424, respectively, which indicate a status. When the training in step S307 ends, “completed” (“Done”) is displayed in the status display field cells 416 and 425. In this way, the processing in FIG. 3A ends (step S308).

When a plurality of feature identifiers 45 can be used, a model name input field 426 (“Model Name”) is clicked and a trained model in the storage is selected, whereby the feature identifier 45 used for the visual field search can be selected.

In the embodiment, a cascade classifier is used as a method of machine learning. Alternatively, an object detection algorithm using deep neural networks (DNN) can also be used.

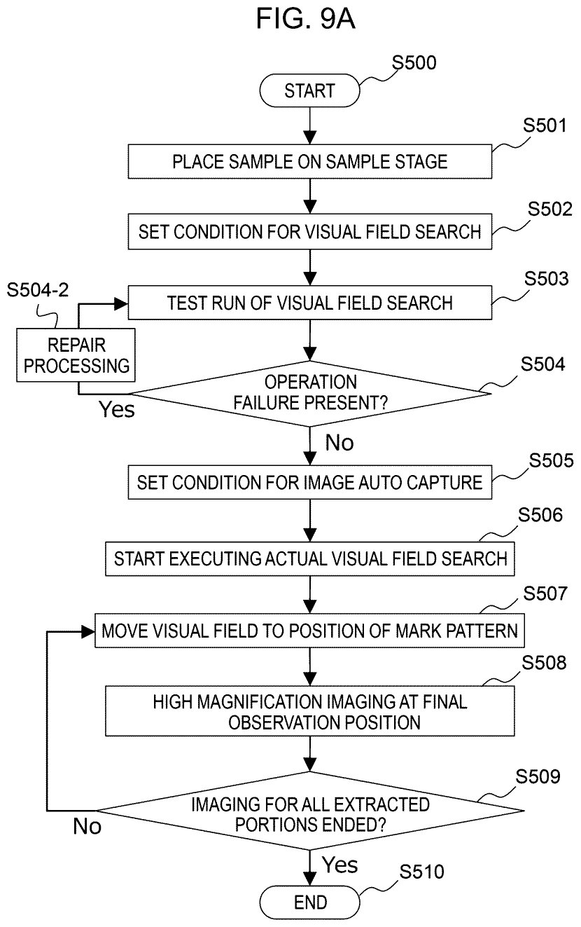

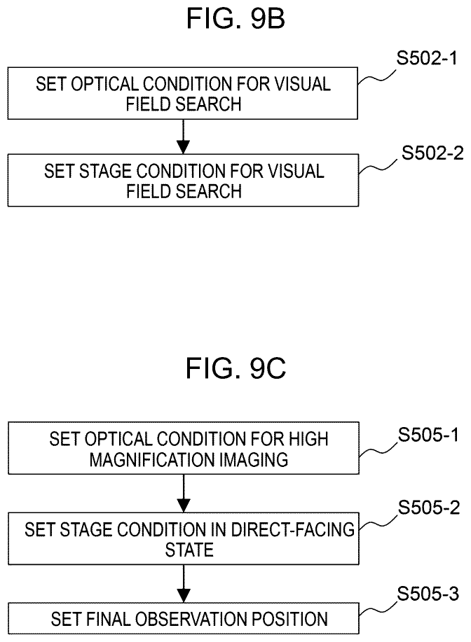

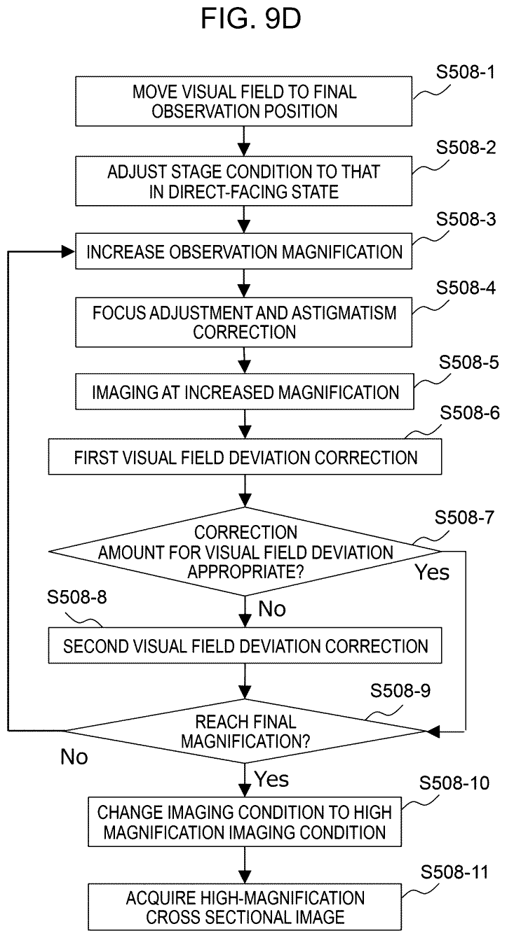

Next, after completion of the training of the feature identifier 45, visual field search utilizing the feature identifier 45 and an automatic imaging sequence will be described with reference to FIGS. 9A to 12. FIG. 9A is a flowchart illustrating an entire automatic imaging sequence. After processing in FIG. 9A is started (step S500), first, a new sample 20 is placed on the sample stage 17 (step S501), and then setting of conditions for visual field search is performed (step S502).

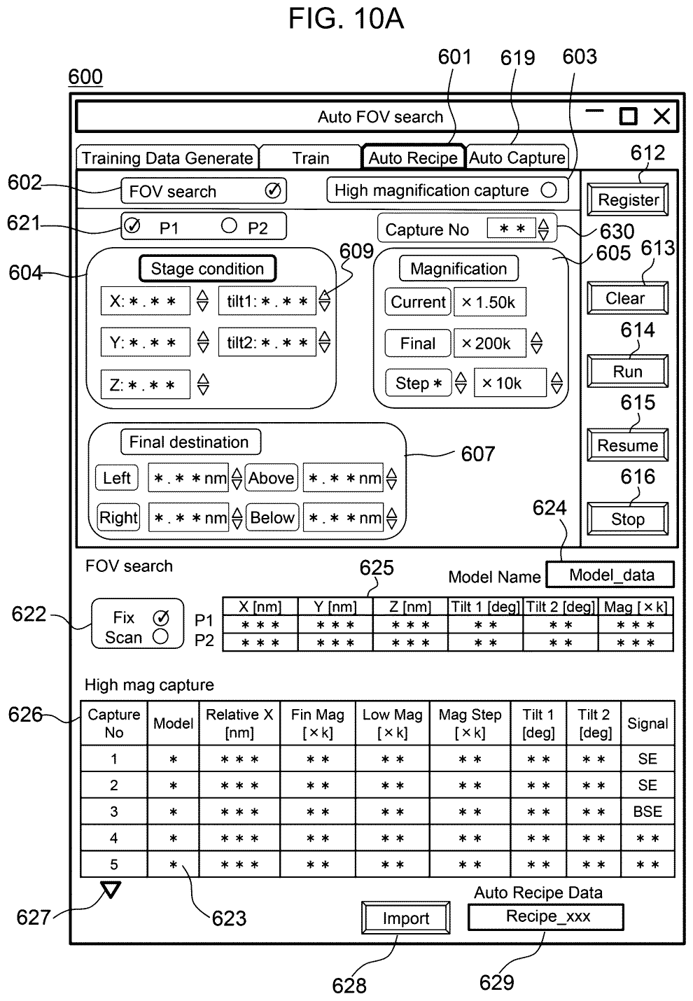

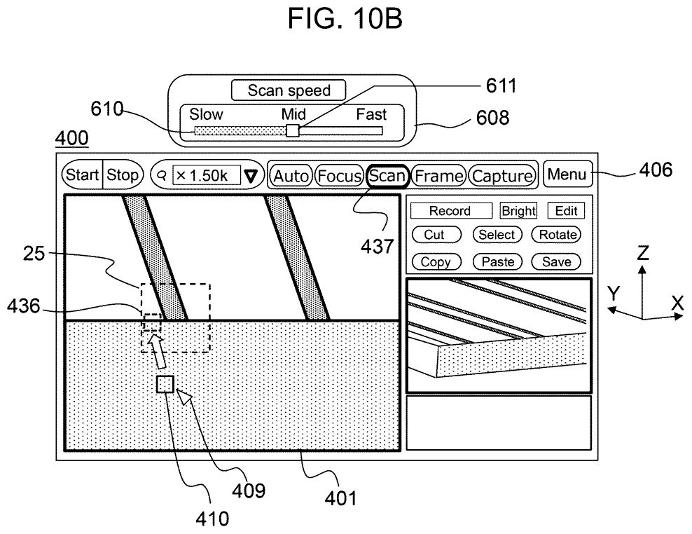

As illustrated in FIG. 9B, the step of setting conditions for visual field search in step S502 includes a step of setting optical conditions for visual field search (step S502-1) and a step of setting stage conditions for visual field search (step S502-2). In step S502, an operation is performed using a GUI 600 illustrated in FIG. 10A and the main GUI 400 illustrated in FIG. 10B, and details thereof will be described later.

When the setting of conditions for visual field search is ended, a test run of the visual field search (step S503) is executed (FIG. 9A). The test run is a step of acquiring a tilt image of the sample 20 at a preset magnification and outputting center coordinates of the mark pattern from the feature identifier 45. A tilt image of a sample cross section may be included in one image depending on the number of target imaging portions and a set magnification, and in that case, it may be essential to capture a plurality of images.

In the case of capturing a plurality of images, the image acquisition is repeated in the following manner: after an image is acquired, the computer system 32 automatically moves the sample stage 17 by a fixed distance in the X-axis direction to acquire a next image thereafter, and further moves the sample stage 17 by the fixed distance to acquire a next image. The feature identifier 45 is operated to detect the mark pattern 23 in the plurality of tilt images thus acquired. A detection result is displayed on the main GUI 400 in such a mode that a marker (for example, a rectangular frame) indicating an ROI is displayed on the acquired image in a superimposed manner. Based on an obtained output result, the operator confirms whether the ROI of the mark pattern included in the image is correctly extracted.

When the operator determines that a failure occurs based on a result of the test run, operation failure elimination processing is performed in step S504-2, and thereafter the step S503 is re-executed or resumed. For example, failures likely to occur include a case where the mark pattern 23 in the visual field is not found even when the feature identifier 45 is operated and center coordinates of the mark pattern 23 are not output, and a case where a region other than the mark pattern 23 is erroneously recognized as the mark pattern 23 and erroneous center coordinates are output. Further, when a failure involving the imaging device or the entire device occurs such as an abnormality of an optical system, execution processing of the test run may be temporarily suspended.

When the test run is successfully performed without occurrence of a failure, condition setting of image auto capture (that is, image acquisition in high magnification image) is performed (step S505). Step S503 of the test run and step S504 of confirming the operation failure may be omitted, and after the setting of conditions for visual field search (step S502), the process proceeds to the step of setting conditions for image auto capture (step S505), and the visual field search may be started immediately.

As illustrated in FIG. 9C, step S505 includes a step of setting optical conditions for high magnification imaging (step S505-1), a step of setting stage conditions in a direct-facing state (step S505-2), and a step of setting a final observation position (step S505-3).

Here, the GUI used at the time of executing the flowcharts in FIG. 9B and FIG. 9C will be described. FIG. 10A illustrates the GUI 600 used by the operator when setting conditions for the visual field search (step S502), and FIG. 10B illustrates an example of the main GUI 400 as the main screen.

The main GUI 400 is the same as the GUI described with reference to FIG. 4A. As described above, when the operator selects the visual field search button from the select button displayed by pressing the menu button 406, the screen shown in FIG. 10A is popped up. When the GUI shown in FIG. 10A is not displayed, if an automatic recipe tab 601 (“Auto Recipe”) is selected, the screen is switched to the GUI shown in FIG. 10A.

In an upper section of the GUI 600 illustrated in FIG. 10A, both imaging conditions for the visual field search (steps S502 and S506) and imaging conditions for high-magnification image automatic imaging (step S508) can be set. By pressing a radio button for either a visual field search field 602 (“FOV search”) or a high magnification imaging field 603 (“High magnification capture”), it is possible to switch between setting screens thereof.

Below the radio button, a setting panel for various settings items of the imaging conditions is displayed. For example, in the case of FIG. 10A, a stage state setting panel 604, a magnification setting panel 605, a final observation position setting panel 607, and the like are displayed in the upper section of the GUI 600.

A position number selection field 621 is a field for selecting a registration number of a position at which the visual field search is to be performed. In the embodiment, two registration numbers P1 and P2 can be set. When there is one position to perform the visual field search, it is sufficient to set only P1. On the other hand, when performing the visual field search while scanning the stage within a certain range, two of P1 and P2 are set so that the visual field can be searched by scanning between the two points.

An imaging number field 630 is a field for selecting a condition set for automatic imaging of a high magnification image. When condition sets are registered, it is possible to refer to one of the registered condition sets by operating the imaging number field 630.

The stage state setting panel 604 is a setting field for registering XYZ coordinate information of the sample stage 17, the first tilt angle (the rotation angle around the first inclination shaft 61 in FIG. 2B), and the second tilt angle (the rotation angle around the second inclination shaft 62 in FIG. 2B) in the computer system 32. Although the tilt image of the sample cross section is displayed on the main screen 401 of the main GUI 400, information of the stage in the state in the image displayed on the main screen 401 is displayed in display fields of X coordinate information, Y coordinate information, Z coordinate information, the first tilt angle (the first inclination shaft 61 in FIG. 2B) and the second tilt angle (the second inclination shaft 62 in FIG. 2B) on the stage state setting panel 604.

When a register button 612 (“Register”) is pressed in a state where P1 or P2 is selected in the position number selection field 621, a current stage state (state of drive shaft) is registered in the computer system 32 as stage information of the selected position number (P1 or P2).

For convenience of description, FIG. 10A illustrates a configuration example of a setting panel displayed on screens for the visual field search (steps S502 and S506) and the high-magnification image automatic imaging (step S508). In reality, each screen displays only the setting panel required for the selection by the radio button. For example, when the radio button of the visual field search field 602 is selected, the position number selection field 621 and the stage state setting panel 604 are displayed, and when the radio button of the high magnification imaging field 603 is selected, the imaging number field 630, the magnification setting panel 605, and the final observation position setting panel 607 are displayed.

The registration can be cancelled by pressing a clear button 613 (“Clear”). Operations of the register button 612 and the clear button 613 are common in the following description.

An execution button 614 (“Run”) is a button for instructing the computer system 32 to start visual field search. By pressing this button, step S503 (test run) in FIG. 9A can be started.

A resume button 615 (“Resume”) is a button for resuming processing when the processing is automatically stopped due to, for example, an operation failure in step S504 in FIG. 9A. After the processing of step S504-2, if the button is pressed after the cause of failure is eliminated, the processing of the test run can be resumed from the step in which the processing is automatically stopped. When a stop button 616 (“Stop”) is pressed, the visual field search being executed can be stopped halfway.

When it is desired to finely adjust the visual field of the tilt image, an adjustment button 609 is pressed, and accordingly XYZ coordinates or the tilt angle of the sample stage 17 changes in a plus or minus direction. The image after change is displayed on the main screen 401 in real time, and the operator registers a state of the sample stage 17 in which the visual field determined to be the most appropriate while viewing the image is obtained. If the visual field is adjusted such that a direct-facing image of the fracture surface 21 appears on the main screen 401 in a state where the radio button of the high magnification imaging field 603 is selected, a stage condition in this state represents a stage condition in a direct-facing state. By registering the stage condition in the computer system 32, step S505-2 in FIG. 9C can be executed.

The setting and/or registration of the stage direct-facing state may be automatically adjusted based on a predetermined algorithm, in addition to the manual adjustment described above. As an algorithm for adjusting an inclination angle of the sample 20, an algorithm may be adopted that acquires tilt images at various inclination angles and calculates an inclination angle by numerical calculation based on the edge line of the wafer extracted from an image.

The magnification setting panel 605 (FIG. 10A) is a setting field for setting an intermediate magnification when the magnification is increased from the imaging magnification in the visual field search (that is, a start magnification in the high magnification imaging) to a final magnification (a final magnification in the high magnification imaging). The imaging magnification of the tilt image currently displayed on the main screen 401 is displayed in a right field of a portion displayed as a “current value” (“Current”). The right side of a “Final” (“Final”) at a middle section is a setting field for setting the final magnification, and the final magnification is selected with an adjustment button similar to that of the stage state setting panel 604. A “step *” (“Step *”) at a lower section is a setting field for setting how many steps the intermediate magnification is from the imaging magnification of the tilt image. When an adjustment button to the right of the setting field is operated, a number appears in the “*” field. For example, “Step 1” or “Step 2” is displayed. On the right side of the adjustment button on the right side of the setting field, a magnification setting field for setting the imaging magnification in each step is displayed, and similarly, the adjustment button is operated to set the intermediate magnification. According to such a GUI, when the magnification is increased over a plurality of steps in the high magnification imaging, it is possible to individually set how many times the step is. After end of the setting, when the register button 612 is pressed, the final magnification and the intermediate magnification that are set are registered in the computer system 32.

The final observation position setting panel 607 is a setting field for setting a center position of the visual field when imaging at the final magnification is performed, based on a relative position from the mark pattern 23. Although the tilt image of the sample cross section is shown together with an ROI 25 for setting the mark pattern on the main screen 401, the operator can set relative position information of the final observation position with respect to the mark pattern 23 by operating the pointer 409 and dragging and dropping the selection tool 410 to a desired final observation position 436 (see FIG. 10B). In the final observation position setting panel 607, a distance in the X direction from center coordinates of the ROI 25 is displayed in either a left display field (“Left”) or a right display field (“Right”), and a distance in the Z direction is displayed in either an upper display field (“Above”) or a lower display field (“Below”).

When setting a plurality of final observation positions, the drag and drop operation of the selection tool 410 is repeated. As will be described later, a numerical value may be directly input to the necessary one of the left display field, the right display field, the upper display field, and the lower display field by using a keyboard, a numeric keypad, or the like provided in the input unit 36. This method provides high convenience for the operator when, for example, taking a position separated from the mark pattern 23 by a predetermined distance as a reference and capturing a plurality of images at a predetermined interval (for example, an equally spaced pitch) determined from the reference position.

The setting of optical conditions for the visual field search and high magnification image capture is performed by using the GUI 400 that is a main GUI. When a button related to optical conditions in the select panel 404 and the operation panel 405 of the GUI 400 is pressed while the GUI 600 is displayed, an optical condition setting screen is displayed.

For example, when a scanning button 437 (“Scan”) is pressed on the GUI in FIG. 10B, a scanning speed setting panel 608 is displayed. The operator can operate a setting knob 611 while watching an indicator 610 to set a scanning speed during the imaging to an appropriate value. When the register button 612 is pressed after the setting, the set scanning speed is registered in the computer system 32.

With the above procedure, optical conditions such as an acceleration voltage, a beam current value, and the like are set while switching the radio buttons of the visual field search field 602 and the high magnification imaging field 603, and are registered in the computer system 32. Accordingly, it is possible to determine the conditions to be used in step S502-1 in FIG. 9B or step S505-1 in FIG. 9C. A scanning speed during imaging a tilt image can be set to be larger than a scanning speed of an image at the final magnification. The scanning electron microscope 10 can switch the scanning speed according to the set speed.

In the above description of the upper stage of FIG. 10A, the numerical value input to the display field provided in each setting panel (stage state setting panel 604, magnification setting panel 605, and final observation position setting panel 607) can be performed using the adjustment button 609. Alternatively or in addition, it is also possible to directly input numerical values using a keyboard, a numeric keypad, or the like provided in the input unit 36.

When a plurality of feature identifiers 45 can be used, a model name input field 624 (“Model Name”) is clicked on the GUI 600 in FIG. 10A and a trained model in the storage is selected, whereby the feature identifier 45 used for the visual field search can be selected.

When setting in the upper section of the GUI 600 in FIG. 10A described above is performed, information is also reflected in a region in the lower section. In the lower section of the GUI 600, a setting condition of the visual field search (“FOV search”) and a setting condition of high magnification image capture are displayed in a list.

Conversely, even if the setting list in the lower section is directly edited, it is equivalent to inputting in the panel in the upper section. For example, if “fixed” (“Fix”) is selected in a visual field search mode setting panel 622 and the stage coordinates and the tilt angle are set in a P1 row of a search position setting table 625, visual field search at a fixed position can be set (at this time, a P2 row of the search position setting table 625 is in an input disabled state).

Alternatively, if “scanning” (“Scan”) is selected in the visual field search mode setting panel 622 and different stage coordinates are set in P1 and P2 of the search position setting table 625, it is possible to set processing of searching for the mark pattern while scanning from P1 to P2.

Also in a high magnification imaging recipe setting table 626, a plurality of imaging portions and imaging conditions can be directly input. With respect to each imaging number (“Capture No”), a relative position from the mark pattern 23 can be set, the observation magnification, the tilt angle, and the like can be set, and it is convenient in the case of continuously setting the high magnification imaging for a large number of conditions. When there are many imaging numbers and the high magnification imaging recipe setting table 626 cannot be fully displayed on the screen, the contents can be scrolled through using a scroll button 627.

It is also possible to select which one of a secondary electron image (SE image) and a backscattered electron image (BSE image) is to be used for the detection signal, and to capture a shape image and a Z contrast image in the same visual field. If the high magnification imaging recipe is described in a CSV file or the like in advance, a recipe name thereof can be input into an automatic recipe name input field 629 (“Auto Recipe Data”), read by pressing an import button 628 (“Import”) and reflected on the GUI 600.

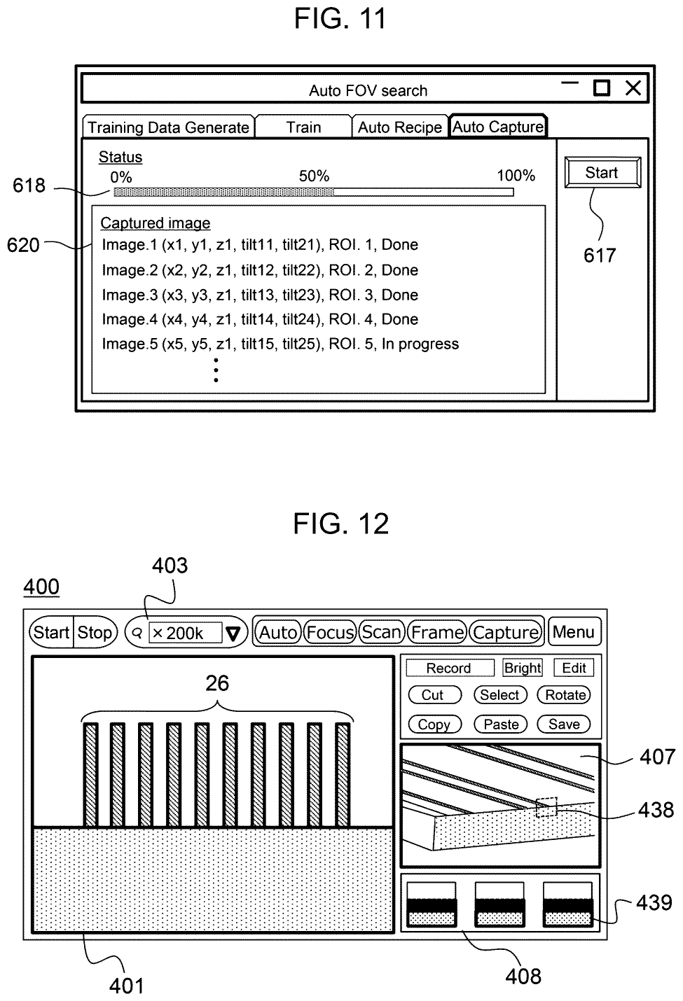

Referring back to FIG. 9A, the description of the flowchart will be resumed. When the setting of conditions for image auto capture is completed in step S505, execution of the actual visual field search is started (step S506). FIG. 11 illustrates a configuration example of a GUI used by the operator when executing the actual visual field search shown in the procedure including step S506 and subsequent steps in FIG. 9A. When the operator selects from the menu button 406 displayed on the main GUI 400 or selects an automatic imaging tab 619 (“Auto Capture”) instead of the automatic recipe tab 601 on the GUI in FIG. 10A, the screen is switched to the GUI in FIG. 11. When the operator presses a start button 617, the procedure including step S506 and subsequent steps in FIG. 9A is started.

In step S506, a tilt image of the sample cross section in a range designated as the imaging condition is captured. Image data obtained from the captured image is sequentially input to the feature identifier 45, and center coordinate data of the mark pattern is output. The output center coordinate data is assigned with a serial number such as ROI 1 and ROI 2, and is stored in the storage 903 together with the supplementary information described above.

When the visual field search ends, a moving amount of the sample stage 17 is calculated by the control unit 33 based on the current stage position information and the center coordinate data of each ROI, and visual field movement to the position of the mark pattern 23 is executed (step S507). After the visual field movement, a high magnification image at the final observation position is acquired according to an image auto capture condition at a high magnification set in step S506 (step S508). Hereinafter, step S508 will be described in detail with reference to FIG. 9D.

After the visual field movement to the position of the mark pattern 23 is performed in step S507 in FIG. 9A, the control unit 33 performs visual field movement to the final observation position according to the relative position information set in the final observation position setting panel 607 in FIG. 10A (step S508-1). Next, in step S508-2, the stage condition is adjusted to that in the direct-facing state. In this step, the control unit 33 calculates a stage moving amount based on a difference between a stage condition set in a state where the radio button of the high magnification imaging field 603 on the GUI in FIG. 10A is pressed and a stage condition (or the stage condition set in a state where the radio button of the visual field search field 602 is pressed) occurring at the end of step S508-1, and operates the sample stage 17.

By the execution of step S508-1 and step S508-2, an observation visual field is moved to the final observation position and the direct-facing state for the sample cross section is satisfied, and thus the magnification is increased in the visual field (step S508-3). The magnification is increased one step at a time according to the intermediate magnifications set in the magnification setting panel 605 in FIG. 10A.

In step S508-4, the computer system 32 performs focus adjustment and astigmatism correction processing. As an algorithm of the correction processing, a method of acquiring an image while sweeping a current value of an objective lens or an aberration correction coil within a predetermined range, performing fast Fourier transform (FFT) or Wavelet transform on the acquired image to evaluate image sharpness, and deriving a setting condition having a high score can be used. If necessary, correction processing of other aberrations may be included. In step S508-5, the computer system 32 performs imaging at an increased magnification, and acquires image data in the current visual field.

In step S508-6, the computer system 32 performs first visual field deviation correction. The first visual field deviation correction of the embodiment includes correction processing of a horizontal line of an image and correction processing of positional deviation in visual field center. Other necessary visual field deviation correction processing may be performed according to the magnification.

First, the correction processing of a horizontal line will be described. As illustrated in FIG. 2A, an observation sample in the embodiment is a coupon sample, and has the upper surface 22 (wafer surface) of the coupon sample on which the mark pattern 23 is formed and the fracture surface 21. The upper surface 22 of the coupon sample is visually recognized as an edge line in a cross sectional image of the fracture surface 21 in the stage direct-facing state. Therefore, in this step, an edge line is automatically detected from the image data acquired in step S508-5, and a visual field deviation in an XZ plane of the acquired image is corrected such that the edge line coincides with the horizontal line (a virtual horizontal reference line passing through the visual field center) in the image. Specifically, actual position coordinates of the edge line are derived by the processor 901 based on position information of the edge line in the image and the position information of the sample stage 17, the rotation angle of the first inclination shaft is adjusted by the control unit 33, and the visual field is moved such that the edge line is positioned at the visual field center. As an image processing algorithm for detecting an edge line, a straight line detection by Hough transform can be used. In order to further improve the detection accuracy, processing of a Sobel filter or the like may be performed, and pre-processing to emphasize the edge line may be performed.

Next, the correction processing of a positional deviation in visual field center will be described. Immediately after the visual field movement in step S508-1, the position set in the final observation position setting panel 607 in FIG. 10A is located at the visual field center. When the observation magnification is increased in step S508-3, the visual field center may be deviated. Therefore, the computer system 32 extracts image data corresponding to an appropriate number of pixels around the visual field center from the image before magnification increase, and uses the image data as a template to execute pattern matching on image data acquired in step S508-5. Regional center coordinates detected by matching indicate the original visual field center. The computer system 32 calculates a difference between the detected regional center coordinates and coordinates of the visual field center of the image data acquired in step S508-5, and transmits the difference as a control amount of the sample stage 17 to the control unit 33. The control unit 33 drives the X drive shaft or the Y drive shaft in accordance with the received control amount, and further drives the second inclination shaft according to the magnification to correct the deviation of the visual field center.

If the computer system 32 includes another feature identifier that is trained using images obtained in the process of magnification increase as training data, coordinate data of the visual field center can be obtained by directly inputting the image data acquired in step S508-5 to the other feature identifier without using template matching.

Further, the visual field deviation correction in this step may be performed not by adjusting the sample stage 17 but by image shift. In this case, an adjustment amount of the visual field deviation is converted into control information regarding a scanning range in XY directions of the electron beam by the computer system 32, and is sent to the control unit 33. The control unit 33 controls the deflection lens 14 based on the received control information, and executes visual field deviation adjustment according to image shift.

In step S508-7, it is determined whether an adjustment amount in the first visual field deviation correction executed in step S508-6 is appropriate. In FIG. 2B, a height of the sample 20 (a distance between the fracture surface 21 and an opposite surface thereof in FIG. 2A) is known, and thus a distance R between a rotation center of the second inclination shaft 62 and the fracture surface 21 is also known. When performing the visual field deviation correction using the second inclination shaft 62 in step S508-6, a rotation angle θ of the second inclination shaft 62 is adjusted such that a product RO of the rotation angle θ and the distance R is equal to a visual field movement amount on the image in principle. However, it is difficult to precisely and accurately measure R for various reasons such as the horizontal accuracy of the wafer placement surface of the sample stage 17 and the inclination (due to the sample shape) of the fracture surface 21. Accordingly, the rotation angle θ calculated in the first visual field deviation correction step may be insufficient or excessive due to the accuracy of R. Further, even in the case of the visual field deviation correction according to the adjustment of the X drive shaft or the Y drive shaft, a case where the original visual field center is not located at the visual field center in the image subjected to the visual field deviation correction may occur due to a problem of mechanical accuracy and the like. If the adjustment amount is not appropriate, the process proceeds to step S508-8. If the adjustment amount is appropriate, the process proceeds to step S508-9.

In step S508-8, second visual field deviation correction is executed. In the second visual field deviation correction, a shortage or an excess of the adjustment amount of the rotation angle θ or adjustment amounts of the X drive shaft and the Y drive shaft are obtained by image processing, and the sample stage 17 is readjusted. When the original visual field center is not located at the visual field center, in step S508-8, an image before execution of movement by a specified distance and the image after the execution of movement are compared, and an actual moving distance is measured and is corrected by adding the shortage. When there is no object to be processed in the visual field, the magnification is changed to a low magnification side, and the processing is performed after an object whose image is identifiable falls within the visual field.

The second visual field deviation correction in this step may be executed by using image shift instead of the adjustment of the sample stage 17. The first visual field deviation correction processing and the second visual field deviation correction processing described above may be collectively referred to as “fine adjustment”.

In step S508-9, it is determined whether the current imaging magnification coincides with the final observation magnification set in the magnification setting panel 605 in FIG. 10A. If the current imaging magnification coincides with the final observation magnification, the process proceeds to the next step S508-10. If the current imaging magnification does not coincide with the final observation magnification, the process returns to step S508-3, and the processing from step S508-3 to step S508-8 is repeated.

In step S508-10, the optical condition is changed to an optical condition for high magnification image capture set on the GUI 400 in FIG. 10A, and in step S508-11, imaging is performed in accordance with the optical condition. With the above steps, step S508 ends, and the process proceeds to step S509 in FIG. 9A.

In step S509, it is determined based on the serial number of the ROI imaged in step S508 whether imaging at the final observation position is completed for all the ROIs extracted in the visual field search. If the imaging is not completed for all ROIs, the process returns to step S507 to perform the visual field movement to the next ROI. If the imaging for all ROIs is completed, automatic imaging processing of the embodiment is ended (step S510).

During execution of the automatic imaging processing, a status indicating a state of progress of the automatic imaging processing is displayed on the GUI in FIG. 11. A status bar 618 displays a ratio of the imaged ROI to the total number of ROIs. In a details field 620 of the captured image, the serial numbers and coordinates (stage condition) of images captured and being captured and the serial numbers of the ROIs corresponding to the mark pattern of the imaging portions are displayed.

As described above, since the scanning electron microscope 10 performs the automatic imaging processing using the feature identifier 45, there is no need for manual visual field search and the work efficiency is improved. Since the generation of the feature identifier 45 is performed based on the image-of-interest supplementary information 541, it can be said that the scanning electron microscope 10 executes the automatic imaging processing based on the image-of-interest supplementary information 541. According to such a configuration, an automatic imaging operation (stage condition, magnification, and the like) is determined based on an actual sample, and thus it is possible to implement an imaging operation suitable for the sample.

FIG. 12 illustrates a state of the main GUI 400 after completion of the sequence of the automatic imaging processing. A captured high magnification image is displayed on the main screen 401, and a tilt image of the fracture surface 21 is displayed on the sub-screen 407 in a wider visual field than the main screen 401. In the image list region 408, high magnification images 439 of respective imaging portions are displayed as thumbnails. The high magnification image displayed on the main screen 401 is a cross sectional image having such a high magnification that a shape of a processing pattern 26 formed on the wafer can be confirmed. In this example, an increase magnification thereof is ×200 k as displayed in the magnification adjustment field 403. In order to highlight an imaging portion of the high magnification image, the mark pattern and a marker 438 indicating a final imaging position are displayed on the sub-screen 407.

In the charged particle beam device described above, the feature identifier 45 of the mark pattern 23 was configured by using 200 sets of training data and the cascade classifier, and the flows in FIGS. 9A to 9D were implemented as an automatic imaging sequence in the device. As a result, favorable automatic cross section observation operations were confirmed. The manual working time required for the preparation of the training image data is 640 minutes in a completely manual method in the related art. In contrast, a semi-automated method according to the embodiment took only five minutes, and the effect of reducing the workload to 1/128 can be obtained with the embodiment.

As described above, according to the scanning electron microscope 10 and the method of outputting image data of interest according to the embodiment, it is possible to semi-automatically generate training image data necessary for training the feature identifier 45. As a result, the time and effort required for visual field search during sample observation can be significantly reduced, and a cross sectional image can be automatically captured.

Although a configuration of semi-automatically generating training image data in step S305 is illustrated in the embodiment, in some cases, the operator may manually generate additional training image data. Also in this case, the main GUI in FIG. 4A can be used. The operator selects, by using the pointer 409 and the selection tool 410, a region including the mark pattern 23 desired to be automatically detected by the feature identifier 45 on a tilt image displayed on the main screen 401. When selecting or editing an image, the operator presses an editing button (“Edit”) in the operation panel 405 on the GUI illustrated in FIG. 4A. When this button is pressed, an image data editing tool such as “cutting” (“Cut”), “copying” (“Copy”) or “saving” (“Save”) is displayed on the screen, and further the pointer 409 and the selection tool 410 are displayed on the main screen 401.

FIG. 4A illustrates a state where one ROI is selected, and a marker indicating the ROI 25 is displayed on the main screen 401. The operator uses the editing tool to clip the selected region from the image data of the tilt image, and stores the selected region in the storage 903 as image data (step S306 in FIG. 3A). The stored image data is training image data used for machine learning. Although only one ROI is selected in FIG. 4A, a plurality of ROIs may be selected in one image. At the time of storage, not only image data but also supplementary information such as optical conditions at the time of imaging including the magnification and scanning conditions and stage conditions (conditions related to setting of the sample stage 17) can be stored in the storage 903.

In the embodiment, the additional acquisition of the ROI image is performed in step S305-3 in FIG. 3B to increase the amount of the training image data. Alternatively, when a sufficient amount of training image data for configuring the feature identifier 45 is obtained by selecting and registering the ROI in step S305-2, step S305-3 is not necessarily required. When the additional acquisition of the ROI image is performed, it is also possible to use only image data related to the additional acquisition as the training image data (that is, it is not necessary to use the image data acquired in step S305-2). As described above, the feature identifier 45 can be generated by machine learning using, as the training data, an image set including at least one of the image data of the ROI and the additional image data of the ROI.

Although the description is made assuming that the time series image data 50 is moving image data in the embodiment, the time series image data 50 may be a data set of multiple images obtained by continuously capturing observation images at a fixed time interval.

In the embodiment, the stage X coordinate, the stage Y coordinate, and the observation magnification are collected as types of data in the operating status time series data 51. Further, the first tilt angle of the stage, the second tilt angle of the stage, the current information of the objective lens, the stigma current information, and the evaluation value of an in-observation image may be collected as other state data. As the evaluation value of an in-observation image, for example, the sharpness calculated by high-frequency component analysis of the image and a luminance feature such as luminance mean or luminance variance calculated based on luminance distribution of the image can be used.

### Second Embodiment

Next, a scanning electron microscope according to a second embodiment will be described. The second embodiment proposes a scanning electron microscope including the sample stage 17 having a structure different from that in the first embodiment. A target sample, a flow of automatic imaging, and a method of configuring a visual field recognition function are the same as those in the first embodiment, and a configuration of the sample stage 17 is different.

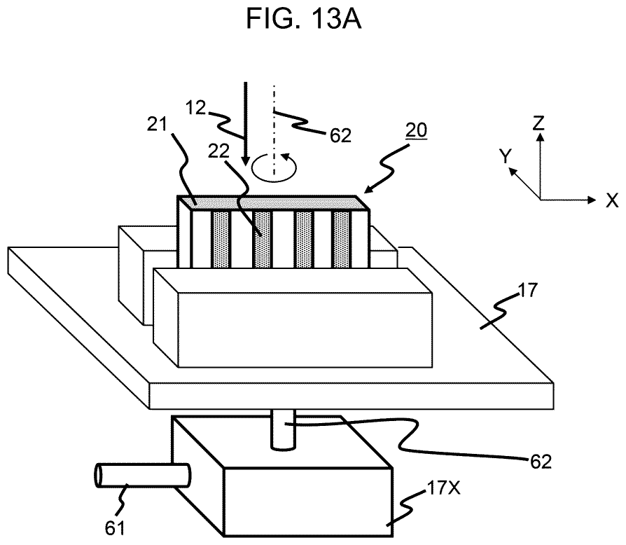

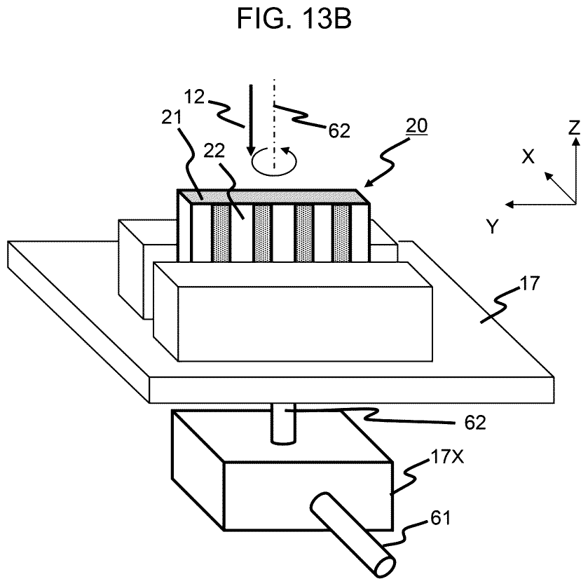

FIG. 13A illustrates a schematic diagram of the sample stage 17. In the embodiment, the second inclination shaft 62 is provided along a Z-axis direction in the drawing. Further, the first inclination shaft 61 is provided on a base 17X on the lower side of the sample stage 17 provided with the second inclination shaft 62. The upper surface 22 of the sample 20 is fixed so as to be orthogonal to an upper surface of the sample stage 17.

FIG. 13B illustrates a state after rotation of the second inclination shaft 62 by 90° (in which a Y-Z plane is parallel to the paper surface) from the state in FIG. 13A (in which an X-Z plane is parallel to the paper surface). In this arrangement, the upper surface 22 of the sample 20 and the first inclination shaft 61 are orthogonal to each other.

By rotating the first inclination shaft 61 from this state, inclination of the fracture surface 21 can be adjusted with respect to the electron beam 12. When acquiring a tilt image to search for the mark pattern 23, the tilt image can be observed by rotating the first inclination shaft 61 after returning to the state of FIG. 13A. Although not shown, the sample stage of the embodiment includes an X drive shaft and a Y drive shaft for independently moving a sample placement surface in XY directions, and an observation visual field can be translated in a longitudinal direction of the sample.

### Third Embodiment

Next, a scanning electron microscope according to a third embodiment will be described. In the embodiment, two feature identifiers 45 are provided, and visual field search in a low-magnification image and visual field search in a high-magnification image are performed. An overall configuration of the charged particle beam device in which an automatic imaging sequence of the embodiment is executed and a GUI used by an operator are the same as those in the first embodiment, and thus repeated description thereof may be omitted in the following description. Differences will be mainly described with appropriate reference to FIGS. 3A, 3B, 9A to 9D, and 10A as needed.

In the embodiment, a configuration flow of the feature identifier 45 is the same as that in the first embodiment illustrated in FIGS. 3A and 3B, but a difference is that there are two objects to be automatically recognized. In the embodiment, a first feature identifier that automatically detects the mark pattern 23 at a low magnification is configured using the same method as in the first embodiment, and further, a second feature identifier that automatically detects the processing pattern 26 (FIG. 12) at a final observation magnification is also configured using the same method as in the first embodiment.

In the embodiment, the flow up to the middle of the automatic imaging sequence is the same as the flow illustrated in FIG. 9A. In step S506 in FIG. 9A, the visual field search is performed by using the configured first feature identifier with the mark pattern 23 as a target object. In the embodiment, processing executed at the time of high magnification imaging at the final observation position in step S508 is partially different from that in the first embodiment.

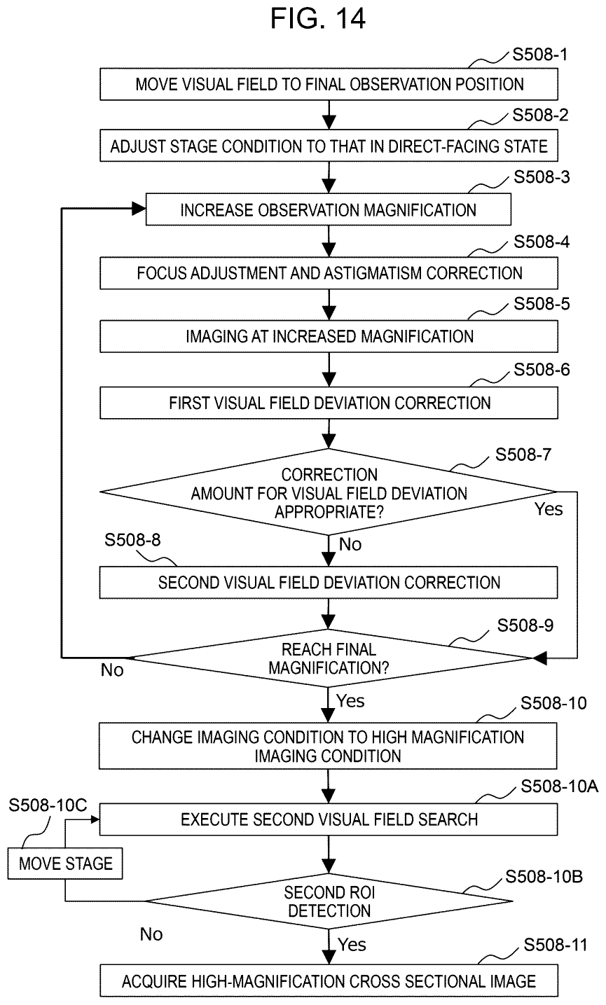

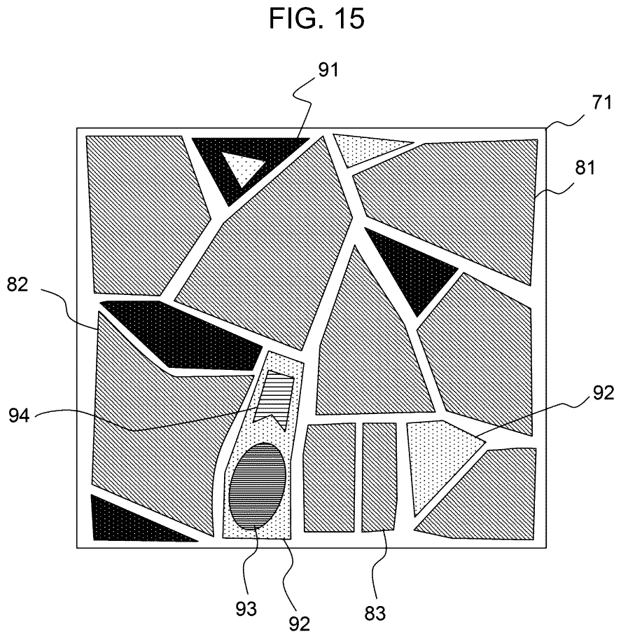

FIG. 14 illustrates a flowchart of main parts of the automatic imaging sequence in the embodiment. The processing from step S508-1 to step S508-10 is the same as in the flowchart in the first embodiment (FIG. 9D).

Thereafter, in S508-10A, second visual field search is performed by using a second feature identifier with the processing pattern 26 as a target object (ROI). If the processing pattern 26 is not found in an observed visual field due to dirt adhering to the processing pattern, deviation of the position of the processing pattern from an assumed position, or the like (step S508-10B: NO), the sample stage 17 is moved in an X or Y direction by one visual field or a preset distance (step S508-10C). Therefore, the second visual field search is executed again (step S508-10A). This processing is repeated until the processing pattern 26 as the target object is confirmed. If the ROI is detected in the determination of step S508-10A (step S508-10B: YES), acquisition of a high-magnification cross sectional image is performed in step S508-11.

The setting of the second visual field search in the embodiment can be executed by the GUI in FIG. 10A. A feature identifier setting field 623 (“Model”) for setting a second feature identifier used for high magnification observation is provided in the high magnification imaging recipe setting table 626 in the lower section of FIG. 10A. In a case where the operator sets a second feature identifier, which is configured in advance, in the feature identifier setting field 623, when the automatic imaging sequence is executed, the second visual field search (step S508-10A) is executed according to the processing of the flowchart in FIG. 14.

When a sequence, in which the second visual field search is not executed, is used as in the first embodiment, a scanning person sets nothing in the feature identifier setting field 623 of the high magnification observation, and sets the feature identifier only in the above model name input field 624 in the visual field search setting panel (“FOV search”).

The embodiment is effective, for example, in preventing a situation in which dirt adheres to a cross section of a processing pattern unexpectedly and a shape of the processing pattern cannot be seen in an automatically captured image. In addition, the embodiment is also effective when automatically observing, at a high magnification, not only a cross sectional image obtained by directly facing the fracture surface 21 but also a tilt image in which the sample is slightly inclined. In the tilt image observation at a high magnification, since an observation portion is often out of the visual field due to the inclination of the sample from a direct-facing state, a function of automatically searching for an observation visual field after the inclination is effective in reducing the workload of the operator.

### Fourth Embodiment

Next, a scanning electron microscope according to a fourth embodiment will be described. In the embodiment, an example of an observation method in which the invention is applied to observation of a metal material structure instead of a semiconductor sample will be described.

In a cross section of a metal material structure, features such as a type and distribution of a plurality of heterogenous phases and a shape and composition of each phase appear. An operator focuses on these features, selects a visual field, and obtains an observation image. In the case of a metal structure having a complicated structure, there are many regions to be focused on. In particular, in an experiment of material development, a metal material structure formed under a new manufacturing condition is observed, and in many cases, it is not clear what kind of structure feature there is until the observation is performed.

In such a case, the operator observes various portions in an observation sample (first observation), first grasps an overall view of what kind of structure is formed, determines a structure feature to be focused on, and acquires an observation image in a visual field including a region where the structure feature appears. It is often the case that detailed observation is performed by returning again to the position where the structure feature to be focused appears, and it takes time to search for the visual field.

In the first observation, the operator may advance the observation while being unsure whether a certain structure feature is worthy of detailed analysis. As a result, when the operator later finds that a region should have been analyzed in detail, the operator may have forgotten to record the position where the structure feature appeared and then be unable to go back to the structure. In order to efficiently advance such observation of a material structure in a limited machine time, a function capable of extracting later a visual field focused on by the operator is effective, and the technique of the disclosure can be applied. The embodiment will be described below, assuming the same device configuration as that illustrated in FIG. 1, which is the same as in the above-described embodiments.

As an example of observing a metal material, FIG. 15 illustrates a schematic diagram of a cross section of a polycrystalline structure 71 of a metal material having the polycrystalline structure. As illustrated, in the polycrystalline structure, a plurality of heterogenous phases coexist with a main phase. In such a structure, while confirming features of a region of a first main phase 81, a region of a first heterogenous phase 91, a region of a third heterogenous phase 93 surrounded by a second heterogenous phase 92, a region of a fourth heterogenous phase 94 surrounded by the second heterogenous phase 92, a region of the second heterogenous phase 92 present alone, a region of a second main phase 82 having a constricted shape, and a region of a third main phase 83 having a large aspect ratio, the operator considers which region should be analyzed in detail, and advances the observation (first observation) of the entire sample while moving to another visual field.

When performing the first observation, in the embodiment, the operator presses the recording button 451 on the main GUI in FIG. 4A, and starts recording the time series image data 50 being observed and the operating status time series data 51 of the device.

When the first observation ends, the operator presses the image extraction button 513 on the GUI in FIG. 4B. As a result, the image 523 of interest estimated to be focused on by the operator according to the algorithm described with reference to FIG. 5 is output.

Thereafter, as in the first embodiment, the ROI selection button 514 on the GUI of FIG. 4B is pressed to activate the ROI selection GUI in FIG. 4C. After the ROI is selected and registered, the setting button 521 on the GUI in FIG. 4B is pressed to activate the GUI for setting the additional imaging in FIG. 4D. Therefore, after the observation magnification is set, the automatic collection button 515 in FIG. 4B is pressed to automatically acquire an observation image of a region including a structure of interest.

Although semi-automatic generation of training image data as in the first embodiment is not intended in the embodiment, it is also possible to automate additional observation of a region of interest in the observation of a metal material structure by outputting image data of interest using a scanning electron microscope, and it is possible to reduce the workload of an operator. That is, even when the feature identifier 45 is not generated, the workload can be reduced.

The invention is not limited to the above-described embodiments, and includes various modifications. For example, the embodiments described above have been described in detail to facilitate understanding of the invention, and the invention is not necessarily limited to those including all the configurations described above. In addition, a part of a configuration according to a certain embodiment can be replaced with a configuration according to another embodiment, and a configuration according to another embodiment can be added to a configuration according to a certain embodiment. In addition, another configuration can be added to, deleted from, or replaced with a part of a configuration of each embodiment. A part or all of the above configurations, functions, processing units, processing means, and the like may be implemented by hardware, for example, by designing an integrated circuit.

### REFERENCE SIGNS LIST

10 scanning electron microscope (charged particle beam device)
11 electron gun (imaging unit)
12 electron beam
13 focusing lens
14 deflection lens
15 objective lens
16 secondary electron detector (detector, imaging unit)
17 sample stage
20 sample
21 fracture surface
22 upper surface
23 mark pattern
24 cross-section observation visual field
25 ROI (region of interest)
26 processing pattern
31 image forming unit (image constructor, imaging unit)
32 computer system
33 control unit
34 image processing unit
35 display unit
36 input unit
44 training image database
45 feature identifier
50 time series image data
51 operating status time series data
61 first inclination shaft
62 second inclination shaft
71 polycrystalline structure
81 first main phase
82 second main phase
83 third main phase
91 first heterogenous phase
92 second heterogenous phase
93 third heterogenous phase
94 fourth heterogenous phase
400 main GUI (graphical user interface)
523 image of interest (image data of interest)
541 image-of-interest supplementary information
600 GUI (graphical user interface)
901 processor (output unit)

1. A charged particle beam device comprising:
a sample stage configured to move a sample;
an imaging unit configured to acquire observation image data of the sample;
an output unit configured to digitalize an operating status of the charged particle beam device and output operating status time series data;
a display unit configured to display a graphical user interface for displaying the observation image data and inputting an observation setting parameter; and
a computer system configured to store time series image data in which the observation image data is arranged in time series and execute arithmetic processing relating to the operating status time series data and the observation image data, wherein
a time-point that matches a predetermined specific variation pattern is automatically determined based on the operating status time series data, and
observation image data corresponding to the time-point is acquired from the time series image data and is output as image data of interest.

2. The charged particle beam device according to claim 1, wherein
the imaging unit includes
an electron gun configured to irradiate the sample with a charged particle beam,
a detector, and
an image constructor.

3. The charged particle beam device according to claim 1, wherein
the specific variation pattern includes at least one of
a pattern in which the sample stage is stopped for a predetermined first period of time and a magnification in the first period of time is fixed, or
a pattern in which the sample stage is stopped for a predetermined second period of time and a magnification is changed in the second period of time.

4. The charged particle beam device according to claim 1, wherein
the operating status time series data includes at least one of
position information of the sample stage,
inclination angle information of the sample stage,
rotation angle information of the sample stage,
observation magnification information,
current information of an objective lens,
stigma current information,
acceleration voltage information of the charged particle beam, and
an evaluation value of an in-observation image.

5. The charged particle beam device according to claim 4, wherein
the operating status time series data includes an evaluation value of an in-observation image, and
the evaluation value of an in-observation image includes at least one of
sharpness calculated by high-frequency component analysis of the image, or
a luminance feature calculated based on luminance distribution of the image.

6. The charged particle beam device according to claim 1, wherein
the time series image data is moving image data.

7. The charged particle beam device according to claim 1, wherein
the time series image data is a collective data set of still image data.

8. The charged particle beam device according to claim 1, wherein
the graphical user interface displays the image data of interest,
the charged particle beam device receives designation of a region of interest in an image related to the image data of interest via the graphical user interface, and
the charged particle beam device stores image data of the region of interest and supplementary information of the region of interest.

9. The charged particle beam device according to claim 8, wherein
the supplementary information of the region of interest includes position information of the sample stage corresponding to the region of interest.

10. The charged particle beam device according to claim 8, wherein
the supplementary information of the region of interest includes at least one of
inclination angle information of the sample stage,
rotation angle information of the sample stage, or
observation magnification information.

11. The charged particle beam device according to claim 8, wherein
the charged particle beam device moves the sample stage to a position, at which imaging of the region of interest is possible, using the supplementary information of the region of interest,
the charged particle beam device acquires additional image data of the region of interest in a plurality of imaging conditions, and
the plurality of imaging conditions include a plurality of imaging conditions in which at least one of a magnification, an inclination angle of the sample stage, or a rotation angle of the sample stage is different.

12. The charged particle beam device according to claim 11, wherein
the charged particle beam device includes a feature identifier, and the feature identifier is generated by machine learning using, as training data, an image set including at least one of image data of the region of interest or additional image data of the region of interest, and
the charged particle beam device executes automatic imaging processing by using the feature identifier.

13. The charged particle beam device according to claim 1, wherein
automatic imaging processing is executed based on supplementary information of the image data of interest.

14. A method for outputting image data of interest by a charged particle beam device,
the charged particle beam device including
a sample stage configured to move a sample,
an imaging unit configured to acquire observation image data of the sample,
an output unit configured to digitalize an operating status of the charged particle beam device and output operating status time series data,
a display unit configured to display a graphical user interface for displaying the observation image data and inputting an observation setting parameter, and
a computer system configured to store time series image data in which the observation image data is arranged in time series and execute arithmetic processing relating to the operating status time series data and the observation image data,
the method comprising:
a step of automatically determining a time-point that matches a predetermined specific variation pattern based on the operating status time series data; and
a step of acquiring observation image data corresponding to the time-point from the time series image data and outputting the observation image data as image data of interest.
